(19) United States
(12) Patent Application Publication
(10) Pub. No.: US 2025/0338730 A1
(43) Pub. Date: Oct. 30, 2025

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Liang YE, Wuhan, Hubei (CN); Cheng WANG, Wuhan, Hubei (CN)

(21) Appl. No.: 18/697,278

(22) PCT Filed: Feb. 26, 2024
(86) PCT No.: PCT/CN2024/078589

§ 371 Date: Mar. 29, 2024

(30) Foreign Application Priority Data
Feb. 8, 2024 (CN) 202410179447.3

(51) Int. Cl. H10K 59/131; H10K 59/121

(52) U.S. Cl. CPC H10K 59/131; H10K 59/1213

(57) ABSTRACT

The present application discloses a display panel and a display device. The display panel includes a first data signal line, a second data signal line, and a plurality of repeat units. A first sub-pixel unit is electrically connected to the first data signal line by a first electrical connection member. A second sub-pixel unit is electrically connected to the second data signal line by a second electrical connection member. The first electrical connection member, the second electrical connection member, the first data signal line, and the second data signal line are disposed on the same side of the repeat units.

### CROSS REFERENCE TO RELATED APPLICATIONS

This application claims the priority of International Application No. PCT/CN2024/078589, filed on Feb. 26, 2024, which claims the priority to Chinese Patent Application No. 202410179447.3, filed on Feb. 8, 2024. The entire disclosures of the above applications are incorporated herein by reference.

### FIELD OF INVENTION

The present application relates to a field of display technologies, especially to a display panel and a display device.

### BACKGROUND OF INVENTION

An organic light emitting diode (OLED) display technology is a new type of display technology that is gradually gaining attention due to its unique advantages such as low power consumption, high saturation, fast response time, and wide viewing angles. It occupies a certain position in the display panel technology field.

In related technologies, the film layer structure of the sub-pixel unit of OLED display panels is the same. The data line is usually set on both sides of the sub-pixel unit, and for the sub-pixel units located in the same column, an electrical connection line crossing the sub-pixel units is required to connect to the corresponding data line. The electrical connection line overlaps with the various film layers in the sub-pixel unit, resulting in a larger parasitic capacitor for the data signal line, thereby affecting data signal transmission and causing abnormalities in display panel performance.

### SUMMARY OF INVENTION

The present application provides a display panel and a display device to solve a technical issue of display abnormalities of a conventional display panel.

To solve the above issue, the present application provides technical solutions as follows:

The present application provides a display panel, comprising a plurality of repeat units, and a first data signal line and a second data signal line disposed on a side of the repeat units, the repeat units comprising at least one first sub-pixel unit and at least one second sub-pixel unit, and each of the first sub-pixel unit and the second sub-pixel unit comprising a pixel driver circuit and a light emitting device connected to the pixel driver circuit;

wherein the display panel further comprises a first electrical connection member and a second electrical connection member, the pixel driver circuit of the first sub-pixel unit is electrically connected to the first data signal line by the first electrical connection member, the pixel driver circuit of the second sub-pixel unit is electrically connected to the second data signal line by the second electrical connection member, and the first electrical connection member, the second electrical connection member, the first data signal line, and the second data signal line are disposed on a same side of the repeat units.

The present application also sets forth a display device, the display device comprising a display panel, and the display panel comprising a plurality of repeat units, and a first data signal line and a second data signal line disposed on a side of the repeat units, the repeat units comprising at least one first sub-pixel unit and at least one second sub-pixel unit, and each of the first sub-pixel unit and the second sub-pixel unit comprising a pixel driver circuit and a light emitting device connected to the pixel driver circuit;

wherein the display panel further comprises a first electrical connection member and a second electrical connection member, the pixel driver circuit of the first sub-pixel unit is electrically connected to the first data signal line by the first electrical connection member, the pixel driver circuit of the second sub-pixel unit is electrically connected to the second data signal line by the second electrical connection member, and the first electrical connection member, the second electrical connection member, the first data signal line, and the second data signal line are disposed on a same side of the repeat units.

### DESCRIPTION OF DRAWINGS

FIG. 1 is a connection view of different sub-pixel units and different data lines in of a conventional display panel;

FIG. 2 is a connection view of different sub-pixel units and different data lines in a display panel of the present application;

FIG. 3 is a structural schematic view of a display panel of the present application;

FIG. 4 is an equivalent circuit diagram of a pixel driver circuit of the display panel of the present application;

FIG. 5 is a film layer schematic view of the display panel of the present application;

FIG. 6 is a film layer view of a first gate electrode layer of the display panel of the present application;

FIG. 7 is a film layer view of a first active layer of the display panel of the present application;

FIG. 8 is a stacked film layer view of the first gate electrode layer and a first active layer of the display panel of the present application;

FIG. 9 is a film layer view of a second gate electrode layer of the display panel of the present application;

FIG. 10 is a stacked film layer view of the first gate electrode layer and a second gate electrode layer of the display panel of the present application;

FIG. 11 is a film layer view of a second active layer of the display panel of the present application;

FIG. 12 is a film layer view of a third gate electrode layer of the display panel of the present application;

FIG. 13 is a film layer view of the first active layer, second active layer, the second gate electrode layer, and the third gate electrode layer of the display panel of the present application;

FIG. 14 is a film layer view of a first source and drain electrode layer of a first sub-pixel unit of the display panel of the present application;

FIG. 15 is a film layer view of the first gate electrode layer, the third gate electrode layer, the first active layer, the second active layer, and the first source and drain electrode layer of the first sub-pixel unit of the display panel of the present application;

FIG. 16 is a film layer view of the second active layer, the second gate electrode layer, and the first source and drain electrode layer of the first sub-pixel unit of the display panel of the present application;

FIG. 17 is a film layer view of the first gate electrode layer, the second gate electrode layer, the third gate electrode layer, the first active layer, the second active layer, and the first source and drain electrode layer of the first sub-pixel unit of the display panel of the present application;

FIG. 18 is a first film layer view of a second source and drain electrode layer of the display panel of the present application;

FIG. 19 is a film layer overlay view of the first active layer, the second active layer, the third gate electrode layer, the first source and drain electrode layer, and the second source and drain electrode layer of the first sub-pixel unit of the display panel of the present application;

FIG. 20 is a film layer overlay view of a pixel driver circuit of the present application;

FIG. 21 is a film layer view of a first source and drain electrode layer of a second sub-pixel unit of the display panel of the present application;

FIG. 22 is a film layer overlay view of a first active layer, a second active layer, a third gate electrode layer, the first source and drain electrode layer, and a second source and drain electrode layer of the second sub-pixel unit of the display panel of the present application;

FIG. 23 is a second film layer view of the second source and drain electrode layer of the display panel of the present application;

FIG. 24 is a film layer view of a third source and drain electrode layer of the display panel of the present application;

FIG. 25 is a film layer overlay view of the second source and drain electrode layer and the third source and drain electrode layer of the display panel of the present application;

FIG. 26 is a fourth film layer overlay view of the pixel driver circuit of the present application;

FIG. 27 is a film layer view of the third source and drain electrode layer in a plurality of sub-pixel units of the display panel of the present application;

FIG. 28 is a connection relationship diagram of a first reset signal line, a second reset signal line, a third reset signal line, and a fourth reset signal line of the display panel of the present application; and

FIG. 29 is a film layer overlay view of the third source and drain electrode layer, a data signal line, and an anode of a light emitting device of the display panel of the present application.

### DETAILED DESCRIPTION OF PREFERRED EMBODIMENTS

The technical solution in the embodiment of the present application will be clearly and completely described below with reference to the accompanying drawings in the embodiments of the present application. Apparently, the described embodiments are merely some embodiments of the present application instead of all embodiments. According to the embodiments in the present application, all other embodiments obtained by those skilled in the art without making any creative effort shall fall within the protection scope of the present application. In addition, it should be understood that the specific embodiments described here are only used to illustrate and explain the present application, and are not used to limit the present application. In the present application, the used orientation terminologies such as “upper” and “lower”, when not specified to the contrary explanation, usually refer to the upper and lower states of the device in actual use or working conditions, specifically according to the direction of the figures in the drawings. Furthermore, “inner” and “outer” refer to the outline of the device.

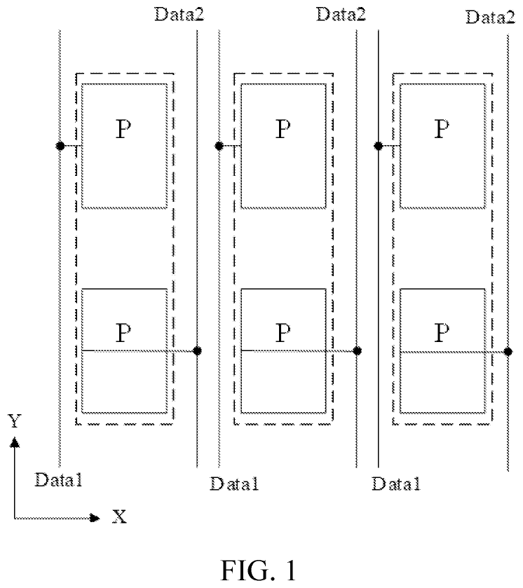

In a conventional technology, pixel driver circuits in different sub-pixel units have the same structure. Namely, input terminals of data signals of the pixel driver circuit are located on the same side. However, data signal lines of the present display panel are located on two sides of the sub-pixel units. For example, in the structure of FIG. 1, a first data signal line Data1 is disposed on a left side of a sub-pixel unit P, a second data signal line Data2 is disposed on a right side of the sub-pixel unit P. Then, a data signal input terminal of the sub-pixel unit P of a first row is disposed adjacent to the first data signal line Data1, and an interval between the data signal input terminal of the sub-pixel unit P of a second row and the second data signal line Data2 is a width of the sub-pixel unit P. Namely, a connection line crossing the sub-pixel unit P is required to electrically connect the second data signal line Data2 to the data signal input terminal of the sub-pixel unit P of a second row: The connection line overlaps a plurality of film layer structures in the sub-pixel unit P. The coupling capacitor between the second data signal line Data2 and a corresponding film layer to further influence data signal transmission of the second data signal line Data2, resulting in abnormalities of the display panel. According to the above technical issue, the present application sets forth a display panel to solve the above technical issue.

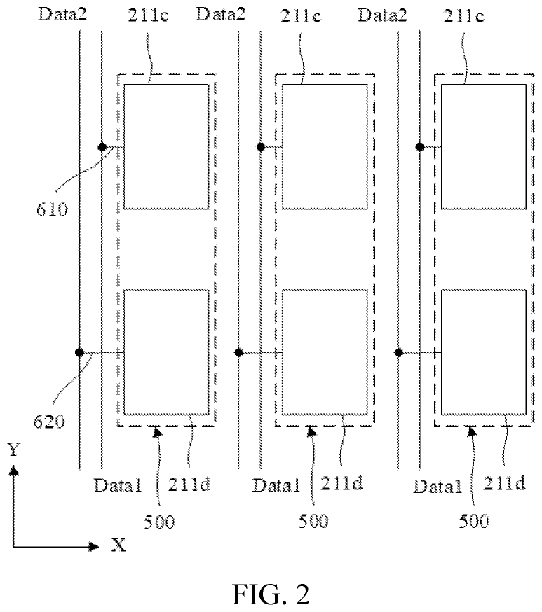

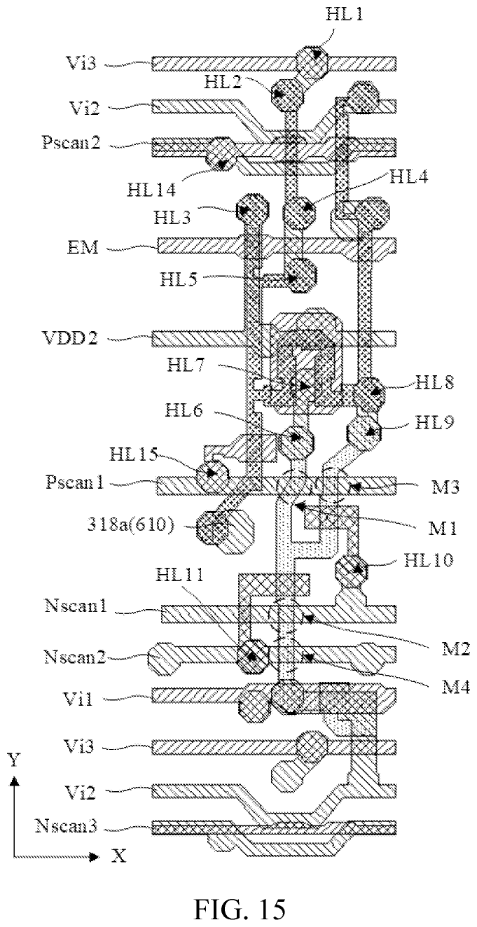

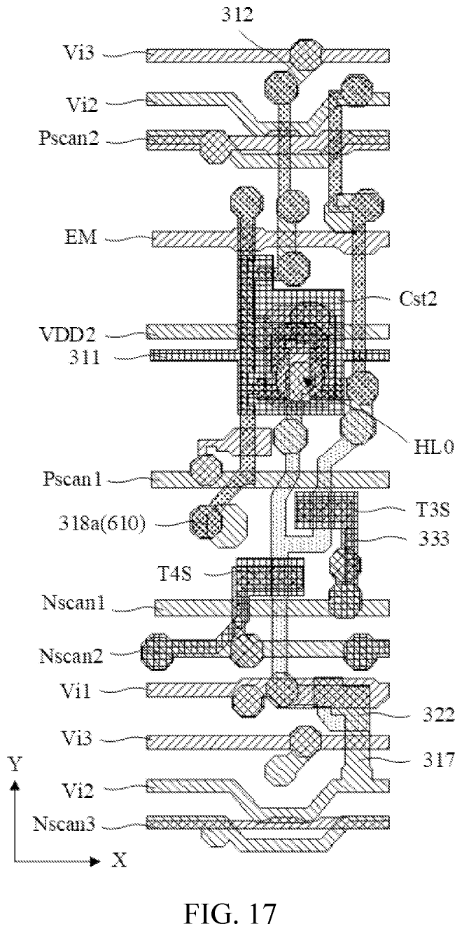

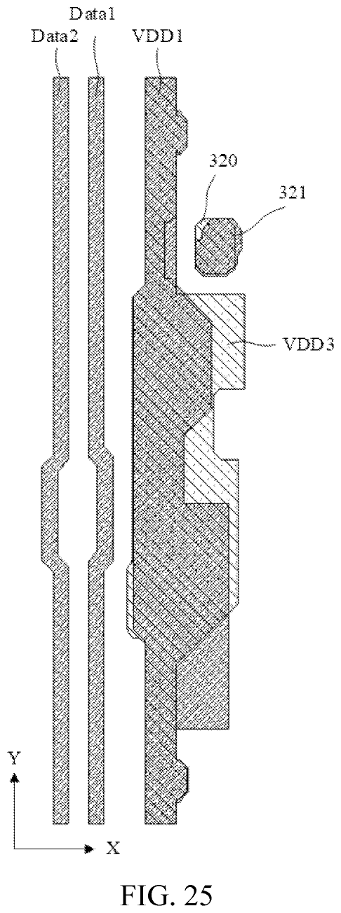

With reference to FIGS. 2 to 28, the present application provides a display panel 100, the display panel 100 can comprise a display portion 200 and a gate electrode driver circuit 300 located on a side of the display portion 200, and the gate electrode driver circuit 300 is configured to input a control signal to the display portion 200.

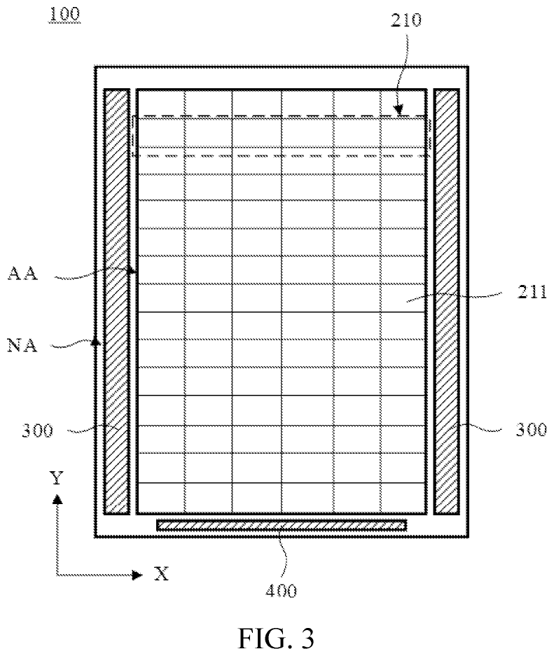

In the present embodiment, with reference to FIG. 3, the display portion 200 comprises a plurality of sub-pixel rows 210, each of the sub-pixel rows 210 comprises a plurality of sub-pixel units 211, and a light emitting device 211b and a pixel driver circuit 211a connected to the light emitting device 211b are disposed in each of the sub-pixel units 211. The gate electrode driver circuit 300 is configured to input a gate electrode control signal to a transistor of the pixel driver circuit 211a.

With reference to FIG. 2, a plurality of the sub-pixel units 211 can comprise a plurality of repeat units 500, the repeat units 500 comprises at least one first sub-pixel unit 211c and at least one second sub-pixel unit 211d. Each of the first sub-pixel unit 211c and the second sub-pixel unit 211d comprises the pixel driver circuit 211a. The following embodiment uses one repeat units 500 having only the first sub-pixel unit 211c and the second sub-pixel unit 211d disposed therein as an example for explanation.

In the present embodiment, the display panel 100 further comprises the first data signal line Data1, and the second data signal line Data2 disposed on a side of the repeat units 500, and a first electrical connection member 610, and a second electrical connection member 620. The pixel driver circuit 211a of the first sub-pixel unit 211c is electrically connected to the first data signal line Data1 by the first electrical connection member 610. The pixel driver circuit 211a of the second sub-pixel unit 211d is electrically connected to the second data signal line Data2 by the second electrical connection member 620.

In the present embodiment, the first electrical connection member 610, the second electrical connection member 620, the first data signal line Data1, and the second data signal line Data2 are disposed on the same side of the repeat units 500.

The present application, by disposing the first data signal line Data1 and the first electrical connection member 610 connected to the first sub-pixel unit 211c in the repeat unit 500 and the second data signal line Data2 and the second electrical connection member 620 connected to the second sub-pixel unit 211d on the same side of the repeat unit 500, reduces a connection distance between a data signal line and an input terminal of a data signal of the sub-pixel unit 211, avoids the first electrical connection member 610 or the second electrical connection member 620 from crossing a corresponding pixel driver circuit 211a, reduces a parasitic capacitor of the data signal line, enhances a stability of the pixel driver circuit 211a, and improves display images of the display panel 100.

It should be explained that structures of the pixel driver circuits 211a of different sub-pixel units 211 in the present application can be the same except for the only difference of the different sub-pixel units 211 disposed in different electrical connection members. For example, the second electrical connection members 620 of the first electrical connection member 610 and the second sub-pixel unit 211d in the first sub-pixel unit 211c are disposed in different locations of the corresponding sub-pixel unit 211.

It should be explained that the light emitting device 211b of the present application can be organic light emitting diode, Mini LED, Micro LED, normal size LED or other light emitting source.

Technical solutions of the present application are described now in combination with specific embodiments.

With reference to FIG. 3, the display panel 100 comprises a display region AA and a non-display region NA disposed adjacent to the display region AA. The display portion 200 is disposed in the display region AA. Optionally, the non-display region NA surrounds the display region AA such that the display region AA is enclosed by the non-display region NA. The display region AA is a region performing the display function in the display panel 100, and a plurality of sub-pixel units 211 performing the display function are disposed in the display region AA. The non-display region NA can be a frame region of the display panel 100, and a function assembly assisting the sub-pixel units 211 in the display region AA to perform display is disposed in the non-display region NA.

With reference to FIG. 3, a bonding terminal 400 is disposed on a lower side of the display region AA, the bonding terminal 400 can be connected to an external circuit. The bonding terminal 400 transmits a signal inputted by the external circuit to a data wiring to drive the display panel 100 to display image. For example, the bonding terminal 400 can be bonded to a chip or chip on film and configured to provide the display panel 100 with power and driver signals.

In the present embodiment, the gate electrode driver circuit 300 is disposed in the non-display region NA, and the gate electrode driver circuit 300 can be disposed on two sides of the display region AA. The gate electrode driver circuit 300 can comprise a plurality of gate electrode driver units in cascade, the gate electrode driver units can be arranged along a first direction X, and the present application has no limit to a structure of the gate electrode driver unit.

In the present embodiment, a plurality of light emitting device 211b and a pixel driver circuit 211a driving the light emitting devices 211b can be disposed in the display region AA. The pixel driver circuit 211a can be a pixel driver circuit 211a of 7T1C, 7T2C, 8T2C, 8T3C, 8T4C. The following embodiment uses the pixel driver circuit 211a of 8T3C as an example for explanation. Because structures of the pixel driver circuits 211a of different sub-pixel units 211 are the same, the structure of the pixel driver circuit 211a of the first sub-pixel unit 211c is described as follows first.

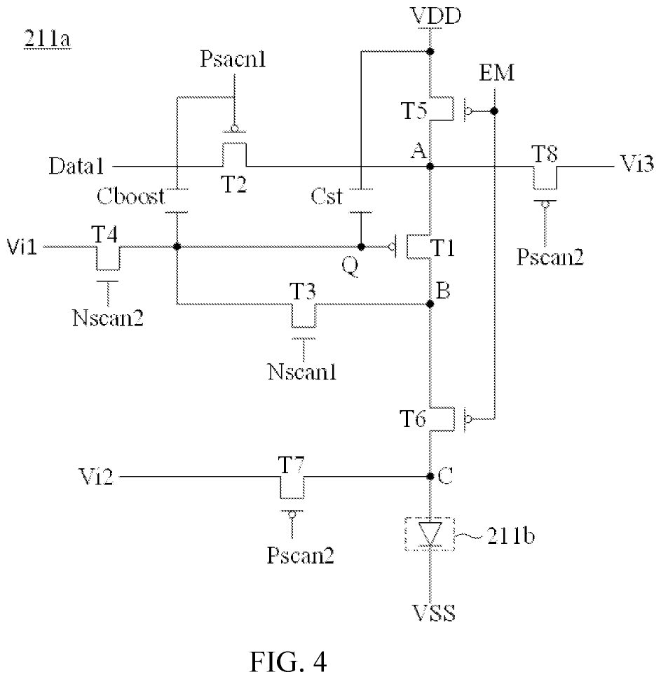

With reference to FIG. 4, the pixel driver circuit 211 a can comprise a switch transistor T2, a driver transistor T1, a compensation transistor T3, a first reset transistor T4, a second reset transistor T7, a third reset transistor T8, a first light emitting transistor T5, a second light emitting transistor T6, a boost capacitor Cboost, and a storage capacitor Cst. The storage capacitor Cst comprises a first electrode plate Cst1 and a second electrode plate Cst2. The boost capacitor Cboost comprises a third electrode plate and a fourth electrode plate.

With reference to FIG. 4, a first electrode of the switch transistor T2 is connected to the first data signal line Data1, a second electrode of the switch transistor T2 is connected to a first node A, and a switch gate electrode T2G of the switch transistor T2 is connected to a second control signal line Pscan1. A first electrode of the driver transistor T1 is connected to the first node A, a second electrode of the driver transistor T1 is connected to a second node B, and a driver gate electrode T1G of the driver transistor T1 is connected to a third node Q. A first electrode of the compensation transistor T3 is connected to the third node Q, a second electrode of the compensation transistor T3 is connected to the second node B, and a compensation gate electrode T3G of the compensation transistor T3 is connected to a first control signal line Nscan1. A first electrode of the first reset transistor T4 is connected to a first reset signal line Vi1, a second electrode of the first reset transistor T4 is connected to the third node Q, and a first reset gate electrode T4G of the first reset transistor T4 is connected to a third control signal line Nscan2. A first electrode of the second reset transistor T7 is connected to a second reset signal line Vi2. A second electrode of the second reset transistor T7 is connected to an anode of the light emitting device 211b. A second reset gate electrode T7G of the second reset transistor T7 is connected to the fourth control signal line Pscan2. A first electrode of the third reset transistor T8 is connected to a third reset signal line Vi3. A second electrode of the third reset transistor T8 is connected to the first node A. A third reset gate electrode T8G of the third reset transistor T8 is connected to a fourth control signal line Pscan2. A first electrode of the first light emitting transistor T5 is connected to a first high electrical potential line VDD1. A second electrode of the first light emitting transistor T5 is connected to the first node A. A first light emitting gate electrode T5G of the first light emitting transistor T5 is connected to a light emitting signal line EM. A first electrode of the second light emitting transistor T6 is connected to the second node B. A second electrode of the second light emitting transistor T6 is connected to an anode of the light emitting device 211b. A second light emitting gate electrode T6G of the second light emitting transistor T6 is connected to the light emitting signal line EM. A third electrode plate of the boost capacitor Cboost is connected to the third node Q. A fourth electrode plate of the boost capacitor Cboost is connected to the second control signal line Pscan1. The first electrode plate Cst1 of the storage capacitor Cst is connected to the third node Q. The second electrode plate Cst2 of the storage capacitor Cst is connected to the first high electrical potential line VDD1.

It should be explained that for the switch transistors T2 in the different sub-pixel units 211, data signal lines connected thereto are different, and the present application only employs one as an example for explanation.

In the present embodiment, the first high electrical potential line VDD1 is configured to provide the pixel driver circuit 211a with a constant voltage high level, and a first low electrical potential line VSS is configured to provide the pixel driver circuit 211a with a constant voltage low level.

In the present embodiment, the switch transistor T2, the driver transistor T1, the second reset transistor T7, the third reset transistor T8, the first light emitting transistor T5, the second light emitting transistor T6 can be one of a P-type transistor and a N-type transistor, and the compensation transistor T3, and the first reset transistor T4 can be the other of the P-type transistor and the N-type transistor. The present application uses the switch transistor T2, the driver transistor T1, the second reset transistor T7, the third reset transistor T8, the first light emitting transistor T5, and the second light emitting transistor T6 being P-type transistors, and the compensation transistor T3 and the first reset transistor T4 being N-type transistors as an example for explanation.

In the present embodiment, a capacitor value of the boost capacitor Cboost is less than a capacitor value of the storage capacitor Cst. In the present embodiment, the storage capacitor Cst is mainly configured to maintain stability of an electric potential of the third node Q. Therefore, the storage capacitor Cst has a greater capacitor. For example, the capacitor value of the storage capacitor Cst can range from 45 fF to 55 fF, and the capacitor value of the boost capacitor Cboost can range from 5 fF to 15 fF.

In the present embodiment, the first electrode can be one of a source electrode and a drain electrode, and the second electrode can be the other of the source electrode and the drain electrode.

In the following embodiment, an included angle between the first direction X and a second direction Y is greater than 0 and is less than or equal to 90°, for example, the first direction X is horizontal, and the second direction Y is vertical.

A film layer structure of the pixel driver circuit 211a of the present application is described as follows according to the structure of FIG. 4.

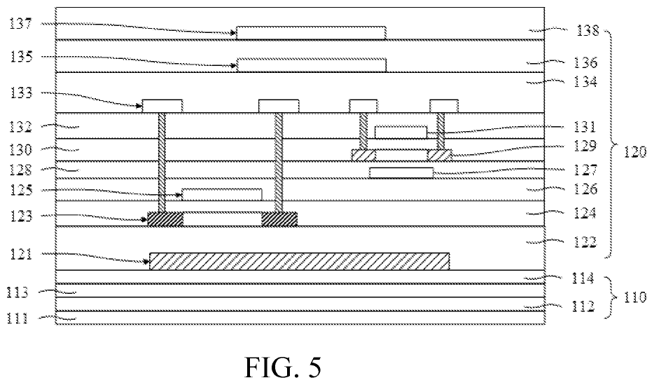

With reference to FIG. 5, an underlay substrate 110 and an array driver layer 120 disposed on the underlay substrate 110 can be disposed in the display region AA and the non-display region NA of the display panel 100. In the display region AA, the display panel 100 can also comprise a pixel definition layer (not shown) disposed on the array driver layer 120, a light emitting device layer (not shown) disposed in the same layer with the pixel definition layer, and an encapsulation layer (not shown) disposed on the pixel definition layer. The film layer structure of the display region AA will be mainly described as follows.

In the present embodiment, the underlay substrate 110 supports each layer disposed on the underlay substrate 110. When the display panel 100 is a bottom emission light emitting display device or dual surface emission light emitting display device, a transparent underlay substrate is used. When the display panel 100 is a top emission light emitting display device, a translucent or opaque underlay substrate and a transparent underlay substrate can be used.

In the present embodiment, the underlay substrate 110 is configured to support each film layer disposed on the underlay substrate 110. The underlay substrate 110 can be formed by insulative material such as glass, quartz, or polymer resin. The underlay substrate 110 can be a rigid underlay or a bendable, foldable, curveable flexible underlay. An example of the flexible material for the flexible underlay comprises but is not limited to polyimide (PI).

In the present embodiment, the underlay substrate 110 can comprise a first flexible base 111, a first barrier layer 112, a second flexible base 113, and a second barrier layer 114 stacked on one another. The first flexible base 111 and the second flexible base 113 can be formed be the same material such as polyimide. The first barrier layer 112 and the second barrier layer 114 can be formed by at least one of inorganic material such as SiOx and SiNx.

In the present embodiment, the first flexible base 111 is formed by coating polymer material on a support base (not shown) and curing the polymer material, the second flexible base 113 is formed by coating material the same as that of the first flexible base 111 and curing the material, and the second flexible base 113 is formed by a method the same as that forming the first flexible base 111. Each of the first flexible base 111 and the second flexible base 113 can form a thickness ranging from 8 μm to 12 μm. Furthermore, When the underlay substrate 110 is formed by the first flexible base 111 and the second flexible base 113, pores and cracks formed during manufacturing the first flexible base 111 are covered by the second flexible base 113 to remove the above defects.

With reference to FIG. 5, the array driver layer 120 can comprise a plurality of thin film transistors, thin film transistors can be an etch stop type and a rear channel etch type, or according to locations of the gate electrode and the active layer be classified into structures such as bottom gate thin film transistors and top gate thin film transistors, or according to performances of the thin film transistors be classified into N-type thin film transistors, P-type thin film transistors. The thin film transistors in FIG. 5 do not represent any structure view of the transistors in FIG. 4 and are only a schematic view of each film layer of the display panel 100 of the present application.

With reference to FIG. 5, the array driver layer 120 can comprise a light shielding layer 121 disposed on the underlay substrate 110, a buffer layer 122 disposed on the light shielding layer 121, a first active layer 123 disposed on the buffer layer 122, a first gate insulation layer 124 disposed on the first active layer 123, a first gate electrode layer 125 disposed on the first gate insulation layer 124, a second gate insulation layer 126 disposed on the first gate electrode layer 125, a second gate electrode layer 127 disposed on the second gate insulation layer 126, a third gate insulation layer 128 disposed on the second gate electrode layer 127, a second active layer 129 disposed on the third gate insulation layer 128, a fourth gate insulation layer 130 disposed on the second active layer 129, a third gate electrode layer 131 disposed on the fourth gate insulation layer 130, a first interlayer insulation layer 132 disposed on the third gate electrode layer 131, a first source and drain electrode layer 133 disposed on the first interlayer insulation layer 132, a second interlayer insulation layer 134 disposed on the first source and drain electrode layer 133, a second source and drain electrode layer 135 disposed on the second interlayer insulation layer 134, a third interlayer insulation layer 136 disposed on the second source and drain electrode layer 135, a third source and drain electrode layer 137 disposed on the third interlayer insulation layer 136, and a planarization layer 138 disposed on the third source and drain electrode layer 137.

With reference to FIG. 5, the light shielding layer 121 is disposed on the second barrier layer 114. The light shielding layer 121 is configured to shield external light from entering through a bottom portion into a thin film transistor. Material of the light shielding layer 121 can be made of black light shielding material, for example, black light shielding metal or black organic material.

With reference to FIG. 5, the buffer layer 122 is disposed on the light shielding layer 121. The buffer layer 122 is configured to isolate the light shielding layer 121 from an upper layer metal material. Material of the buffer layer 122 can comprise nitrogen element and a composite composed of silicon element and oxygen element, for example, single silicon oxygen film layer, or a lamination structure of silicon oxygen-silicon nitride.

With reference to FIG. 5, the first active layer 123 is disposed on the buffer layer 122. The second active layer 129 can be disposed on the third gate insulation layer 128. Material of the first active layer 123 and the second active layer 129 can be indium gallium zinc oxide semiconductor, amorphous silicon, or low-temperature polycrystalline silicon. For example, in the present application, material of the first active layer 123 can be low-temperature polycrystalline silicon, and material of the second active layer 129 can be indium gallium zinc oxide semiconductor.

With reference to FIG. 5, the first gate insulation layer 124, the second gate insulation layer 126, the third gate insulation layer 128, the fourth gate insulation layer 130, the first interlayer insulation layer 132, the second interlayer insulation layer 134, and the third interlayer insulation layer 136 are disposed respectively on corresponding metal layers or semiconductor layers, and are separately disposed on different metal layers or semiconductor layers. Material of the first gate insulation layer 124, the second gate insulation layer 126, the first interlayer insulation layer 132, the third gate insulation layer 128, the fourth gate insulation layer 130, the second interlayer insulation layer 134, and the third interlayer insulation layer 136 can be inorganic substance composed of nitrogen, oxygen, and silicon or organic material with flatness.

With reference to FIG. 5, the first gate electrode layer 125, the second gate electrode layer 127, and the third gate electrode layer 131 are disposed on corresponding insulation layers respectively. Material of the first gate electrode layer 125, the second gate electrode layer 127, and the third gate electrode layer 131 material can be copper, molybdenum or molybdenum titanium alloy, etc. Material of three gate electrode layers of the present application can be molybdenum.

With reference to FIG. 5, the first source and drain electrode layer 133 is disposed on the first interlayer insulation layer 132. The second source and drain electrode layer 135 is disposed on the second interlayer insulation layer 134. The third source and drain electrode layer 137 is disposed on the third interlayer insulation layer 136. Material of the first source and drain electrode layer 133, the second source and drain electrode layer 135, and the third source and drain electrode layer 137 can three layers of material of be copper, molybdenum, molybdenum titanium alloy or titanium aluminum titanium, and material of the three source and drain electrode layers of the present application can be titanium aluminum titanium.

With reference to FIG. 5, the planarization layer 138 is formed on an entire layer to guarantee flatness of the film layer of the array driver layer 120. Material of the planarization layer 138 can be inorganic substance composed of nitrogen, oxygen, and silicon or organic material with flatness.

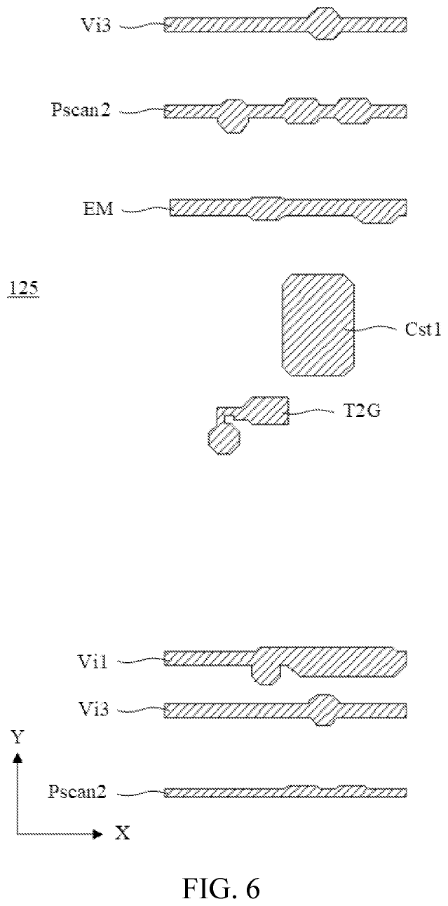

With reference to FIG. 6, the first gate electrode layer 125 comprises the light emitting signal line EM, the first reset signal line Vi1, the third reset signal line Vi3, the fourth control signal line Pscan2, and the light emitting signal line EM. The first reset signal line Vi1, the third reset signal line Vi3, and the fourth control signal line Pscan2 extend along the first direction X, and the third reset signal line Vi3, the fourth control signal line Pscan2, the light emitting signal line EM, and the first reset signal line Vi1 are arranged at intervals along the second direction Y.

With reference to FIG. 6, the first gate electrode layer 125 further comprises the switch gate electrode T2G disposed between the light emitting signal line EM and the first reset signal line Vi1 and the first electrode plate Cst1 of the storage capacitor Cst. The switch gate electrode T2G and the first electrode plate Cst1 are arranged along the second direction Y at an interval. Also, the first electrode plate Cst1 is disposed near the light emitting signal line EM, and the switch gate electrode T2G is disposed away from the light emitting signal line EM.

In the present embodiment, the light emitting signal line EM can directly serve as the first light emitting gate electrode T5G and the second light emitting gate electrode T6G. The fourth control signal line Pscan2 can directly serve as the second reset gate electrode T7G and the third reset gate electrode T8G.

With reference to FIG. 6, the switch gate electrode T2G and the first electrode plate Cst1 can be rectangular, and four corners of the first electrode plate Cst1 can be beveled.

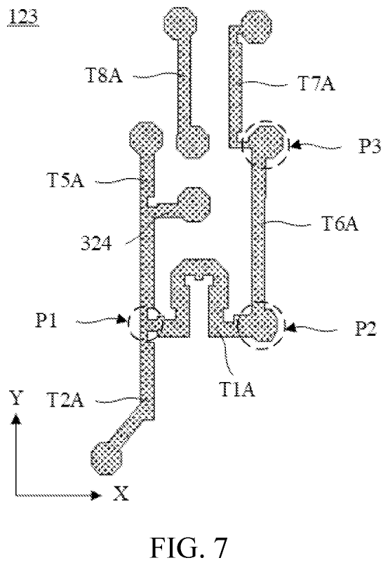

With reference to FIG. 7, the first active layer 123 comprises a switch active portion T2A of the switch transistor T2, a driver active portion T1A of the driver transistor T1, a second reset active portion T7A of the second reset transistor T7, a third reset active portion T8A of the third reset transistor T8, a first light emitting active portion T5A of the first light emitting transistor T5, and a second light emitting active portion T6A of the second light emitting transistor T6.

With reference to FIG. 7, the switch active portion T2A, the driver active portion T1A, the second reset active portion T7A, and the first light emitting active portion T5A, the second light emitting active portion T6A are connected to one another. The third reset active portion T8A is disposed separately from other active portion. The switch active portion T2A, the second reset active portion T7A, the third reset active portion T8A, the first light emitting active portion T5A, and the second light emitting active portion T6A are strip-like and extend along the second direction Y. The driver active portion T1A is U-shaped and disposed between the first light emitting active portion T5A and the second light emitting active portion T6A. A first terminal of the switch active portion T2A, a first terminal of the driver active portion T1A, and a first terminal of the first light emitting active portion T5A are connected to a first connection point P1. A second terminal of the driver active portion T1A and a first terminal of the second light emitting active portion T6A are connected to a second connection point P2. A first terminal of the second reset active portion T7A and a second terminal of the second light emitting active portion T6A are connected to a third connection point P3.

In the present embodiment, the first connection point P1 is the first node A, the second connection point P2 is the second node B, the third connection point P3 is a point location at which an anode of the light emitting device 211b is located.

It should be explained that a pattern of a switch active portion of the first sub-pixel unit 211c is the same as a pattern of a switch active portion of the second sub-pixel unit 211d.

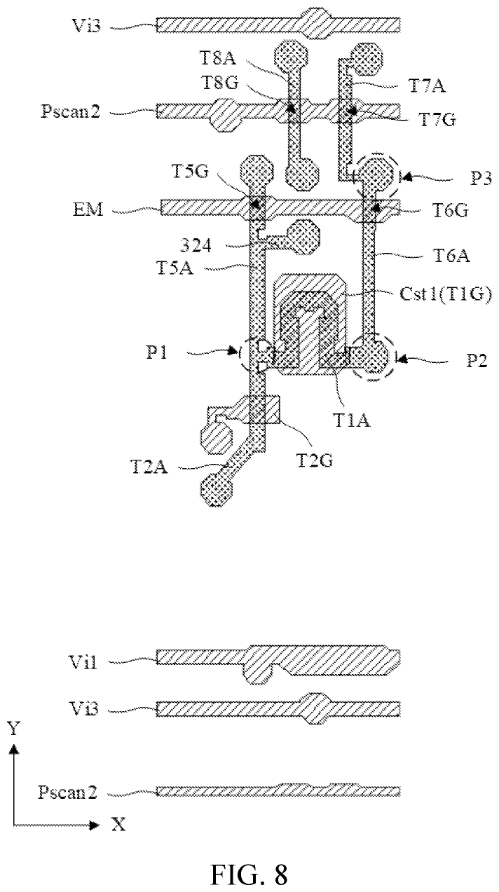

With reference to FIG. 8, the light emitting signal line EM partially overlaps the first light emitting active portion T5A, and an overlap portion is a channel of the first light emitting active portion T5A. The light emitting signal line EM partially overlaps the second light emitting active portion T6A, and an overlap portion is a channel of the second light emitting active portion T6A. The switch gate electrode T2G partially overlaps the switch active portion T2A, and an overlap portion is a channel of the switch active portion T2A. The fourth control signal line Pscan2 partially overlaps the second reset active portion T7A, and an overlap portion is a channel of the second reset active portion T7A. The fourth control signal line Pscan2 partially overlaps the third reset active portion T8A, and an overlap portion is a channel of the third reset active portion T8A. The driver active portion T1A partially overlaps the first electrode plate Cst1, and an overlap portion is a channel of the driver active portion T1A. The first electrode plate Cst1 of the present application is reused as the driver gate electrode T1G of the driver transistor T1.

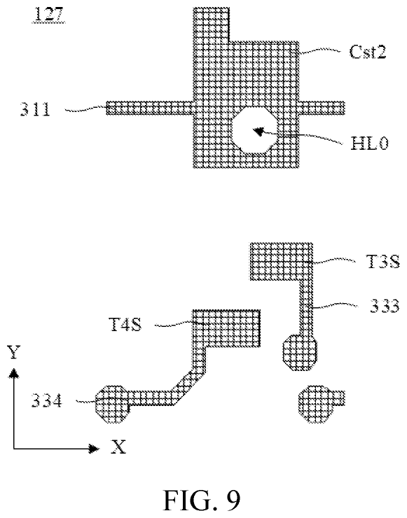

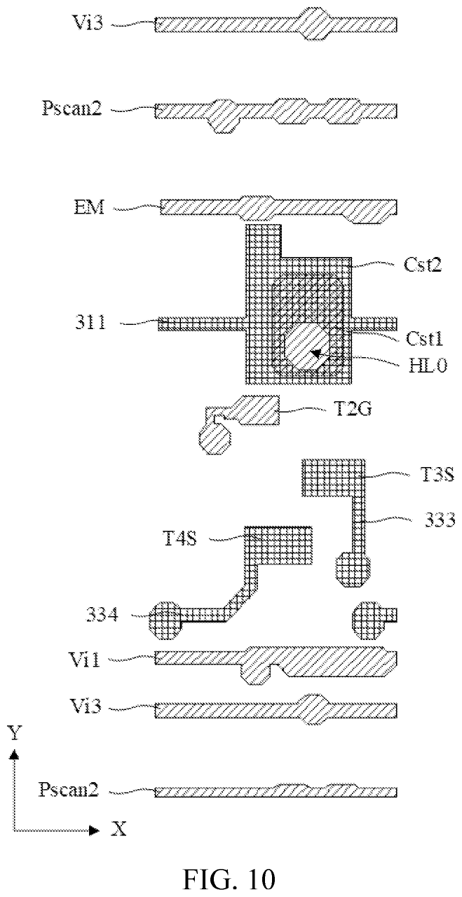

With reference to FIG. 9 and FIG. 10, the second gate electrode layer 127 comprises the second electrode plate Cst2 of the storage capacitor Cst, a first light shielding unit T3S of the compensation transistor T3, a second light shielding unit T4S of the first reset transistor T4, and the second electrode plate Cst2 disposed along the second direction Y. The first light shielding unit T3S and the second light shielding unit T4S are located between the light emitting signal line EM and the first reset signal line Vi1. The first electrode plate Cst1 is disposed near the light emitting signal line EM. The second light shielding unit T4S is disposed near the first reset signal line Vi1. The first light shielding unit T3S is located between the second light shielding unit T4S and the second electrode plate Cst2.

With reference to FIG. 9 and FIG. 10, an area of the second electrode plate Cst2 is greater than an area of the first electrode plate Cst1, and an orthographic projection of the first electrode plate Cst1 on the second electrode plate Cst2 is located within the second electrode plate Cst2. A first via hole HL0 is defined in the second electrode plate Cst2 to expose a portion of the first electrode plate Cst1.

With reference to FIG. 10, the first light shielding unit T3S, the second light shielding unit T4S, and the second electrode plate Cst2 can be rectangular, and at least some corners of the three can be beveled.

With reference to FIG. 10, the second gate electrode layer 127 further comprises first electrical connection sections 311 disposed respectively on two sides of the second electrode plate Cst2. The two first electrical connection section 311 extend along the first direction X. Also, in adjacent two of the sub-pixel units 211 disposed along the first direction X, the second electrode plates Cst2 of the two sub-pixel units 211 are electrically connected to each other by the first electrical connection section 311. The second electrode plate Cst2 of the present embodiment is connected to the first high electrical potential line VDD1. To reduce a resistance on the second electrode plate Cst2, the present application can connect the second electrode plates Cst2 of the sub-pixel units 211 disposed along the first direction X and connect the second electrode plates Cst2 to the first high electrical potential line VDD1 on an upper layer in parallel, thereby reducing resistances of the first high electrical potential line VDD1 and the second electrode plate Cst2.

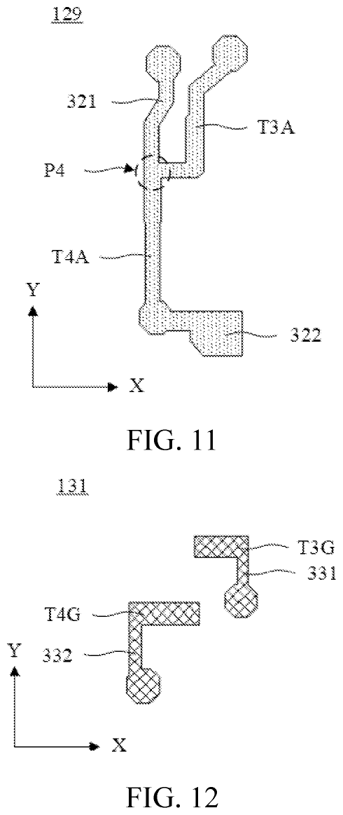

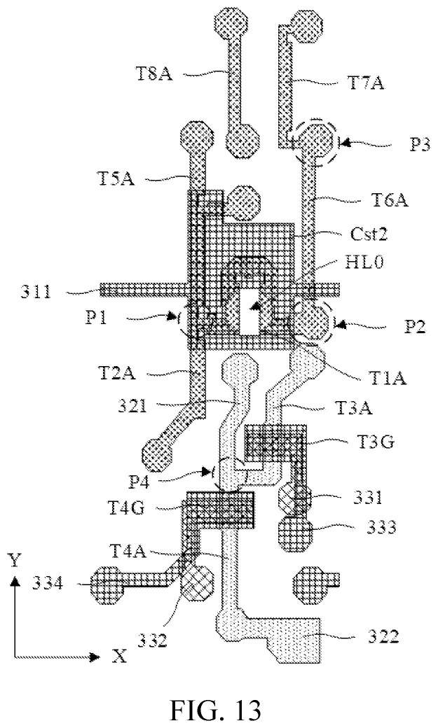

With reference to FIG. 11 and FIG. 13, the second active layer 129 comprises a compensation active portion T3A of the compensation transistor T3 and a first reset active portion T4A of the first reset transistor T4. The compensation active portion T3A and the first reset active portion T4A extend along the second direction Y. A first terminal of the compensation active portion T3A and a first terminal of the first reset active portion T4A are connected to a fourth connection point P4. A second terminal of the compensation active portion T3A extends toward the second connection point P2 and is disposed separately from the second connection point P2. A second terminal of the first reset active portion T4A extends toward the first reset signal line Vi1 and overlaps the first reset signal line Vi1.

In the present embodiment, the fourth connection point P4 can be the third node Q.

With reference to FIG. 11 and FIG. 13, the second active layer 129 further comprises a first extension section 321 connected to the fourth connection point P4 and a second extension section 322 connected to a second terminal of the first reset active portion T4. The first extension section 321 extends along the second direction Y toward a location at which the storage capacitor Cst is located. The first extension section 321 is disposed separately from the storage capacitor Cst. The second extension section 322 extends along the first direction X. The second extension section 322 at least partially overlaps the first reset signal line Vi1.

With reference to FIG. 12 and FIG. 13, the third gate electrode layer 131 comprises the compensation gate electrode T3G and the first reset gate electrode T4G of the first reset transistor T4. An area of the compensation gate electrode T3G is less than an area of the first light shielding unit T3S. An orthographic projection of the compensation gate electrode T3G on the first light shielding unit T3S is located within the first light shielding unit T3S. An area of the first reset gate electrode T4G is less than an area of the second light shielding unit T4S. An orthographic projection of the first reset gate electrode T4G on the second light shielding unit T4S is located within the second light shielding unit T4S.

With reference to FIG. 12 and FIG. 13, the first reset gate electrode T4G partially overlaps the first reset active portion T4A, and an overlap portion is a channel of the first reset active portion T4A. The compensation gate electrode T3G partially overlaps the compensation active portion T3A, and an overlap portion is a channel of the compensation active portion T3A.

With reference to FIG. 12 and FIG. 13, the first reset gate electrode T4G and the compensation gate electrode T3G can be rectangular, and some corners of the first reset gate electrode T4G and the compensation gate electrode T3G can be beveled.

With reference to FIG. 12 and FIG. 13, the third gate electrode layer 131 further comprises a first electrical conduction section 331 connected to the compensation gate electrode T3G and a second electrical conduction section 332 connected to the first reset gate electrode T4G. The first electrical conduction section 331 extends away from a side of the compensation gate electrode T3G along the second direction Y. The second electrical conduction section 332 extends away from a side of the first reset gate electrode T4G along the second direction Y.

With reference to FIG. 9 and FIG. 13, the second gate electrode layer 127 further comprises a third electrical conduction section 333 connected to the first light shielding unit T3S and a fourth electrical conduction section 334 connected to the second light shielding unit T4S. The third electrical conduction section 333 extends away from a side of the compensation gate electrode T3G along the second direction Y. A line width of the first electrical conduction section 331 can be less than or equal to a line width of the third electrical conduction section 333, and an orthographic projection of the first electrical conduction section 331 on the third electrical conduction section 333 can be located within the third electrical conduction section 333. The fourth electrical conduction section 334 can extend away from a side of the first reset gate electrode T4G along the second direction Y first, then can extend away from a side of the compensation transistor T3 along the first direction X. An end of the second electrical conduction section 332 and an end of the fourth electrical conduction section 334 away from the first reset gate electrode T4G can be located on the same level.

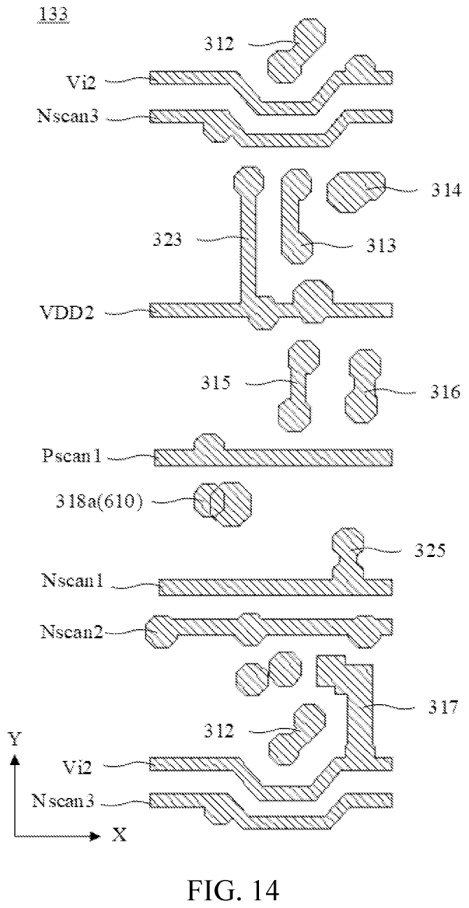

With reference to FIG. 14, the first source and drain electrode layer 133 comprises the second reset signal line Vi2, a second control signal line Nscan3, a second high electrical potential line VDD2, the second control signal line Pscan1, the first control signal line Nscan1, the third control signal line Nscan2 arranged along the second direction Y. The second reset signal line Vi2, the second control signal line Nscan3, the second high electrical potential line VDD2, the second control signal line Pscan1, the first control signal line Nscan1, and the third control signal line Nscan2 can extend along the first direction X.

With reference to FIG. 14 to FIG. 17, the second reset signal line Vi2 is disposed between the third reset signal line Vi3 and the first control signal line Nscan1. The second control signal line Nscan3 partially overlaps the fourth control signal line Pscan2. The second high electrical potential line VDD2 is disposed between the light emitting signal line EM and the first electrical connection section 311. The second control signal line Pscan1, the first control signal line Nscan1, and the third control signal line Nscan2 are disposed between the first electrical connection section 311 and the first reset signal line Vi1, and the second control signal line Pscan1 is disposed near the first electrical connection section 311. The third control signal line Nscan2 is disposed near the first reset signal line Vi1. The first control signal line Nscan1 is disposed between the second control signal line Pscan1 and the third control signal line Nscan2.

With reference to FIG. 14 to FIG. 17, the first source and drain electrode layer 133 further comprises a second electrical connection section 312 disposed between the second reset signal line Vi2 and the third reset signal line Vi3. A first terminal of the second electrical connection section 312 is electrically connected to the third reset signal line Vi3 through a first via hole HL1. A second terminal of the second electrical connection section 312 is electrically connected to a first terminal of the third reset active portion T8A through a second via hole HL2. The third reset signal line Vi3 transmits a reference voltage to the third reset transistor T8 by the second electrical connection section 312.

In the present embodiment, the first via hole HL1 is defined through the second gate insulation layer 126, the third gate insulation layer 128, the fourth gate insulation layer 130, and the first interlayer insulation layer 132. The second via hole HL2 is defined through the first gate insulation layer 124, the second gate insulation layer 126, the third gate insulation layer 128, the fourth gate insulation layer 130, and the first interlayer insulation layer 132.

In the present embodiment, to avoid interference of the second electrical connection section 312 with the second reset signal line Vi2, a portion of the second reset signal line Vi2 corresponding to the second electrical connection section 312 is sunk. Namely, the signal line of the region shifts away from a side of the third reset signal line Vi3. Also, to guarantee a line distance between the second control signal line Nscan3 and the second reset signal line Vi2, the second control signal line Nscan3 is also sunk.

With reference to FIG. 14 to FIG. 17, the first source and drain electrode layer 133 further comprises a third extension section 323, a third electrical connection section 313, and a fourth electrical connection section 314 disposed between the second high electrical potential line VDD2 and the second control signal line Nscan3. The third extension section 323 and the third electrical connection section 313 extend along the second direction Y, and the fourth electrical connection section 314 extends along the first direction X.

In the present embodiment, a first terminal of the third extension section 323 is electrically connected to the second high electrical potential line VDD2. A second terminal of the third extension section 323 extends away from a side of the second high electrical potential line VDD2, and the third extension section 323 overlaps a portion of the first light emitting active portion T5A. Also, a second terminal of the third extension section 323 is electrically connected to a second terminal of the first light emitting active portion T5A through a third via hole HL3. A first terminal of the third electrical connection section 313 is electrically connected to a second terminal of the third reset active portion T8A through a fourth via hole HL4. The first active layer 123 further comprises a fourth extension section 324 connected to the first light emitting active portion T5A. The fourth extension section 324 extends along the first direction X. A second terminal of the third electrical connection section 313 is electrically connected to the fourth extension section 324 through a fifth via hole HL5. The third reset signal line Vi3 transmits the reference voltage to the first connection point P1 by the second electrical connection section 312, the third electrical connection section 313, and the fourth extension section 324 to reset an electric potential of the first node A. An end of the fourth electrical connection section 314 is electrically connected to the third connection point P3 of the first active layer 123 through a via hole. Another end of the fourth electrical connection section 314 is electrically connected to a conductive layer of the second source and drain electrode layer 135 through another via hole.

In the present embodiment, the third via hole HL3 is defined through the first gate insulation layer 124, the second gate insulation layer 126, the third gate insulation layer 128, the fourth gate insulation layer 130, and the first interlayer insulation layer 132. The fourth via hole HL4 and the fifth via hole HL5 are defined through the first gate insulation layer 124, the second gate insulation layer 126, the third gate insulation layer 128, the fourth gate insulation layer 130, and the first interlayer insulation layer 132.

With reference to FIGS. 14 to 17, the first source and drain electrode layer 133 further comprises a fifth electrical connection section 315 and a sixth electrical connection section 316 disposed between the second high electrical potential line VDD2 and the second control signal line Pscan1. The fifth electrical connection section 315 and the sixth electrical connection section 316 extend along the second direction Y.

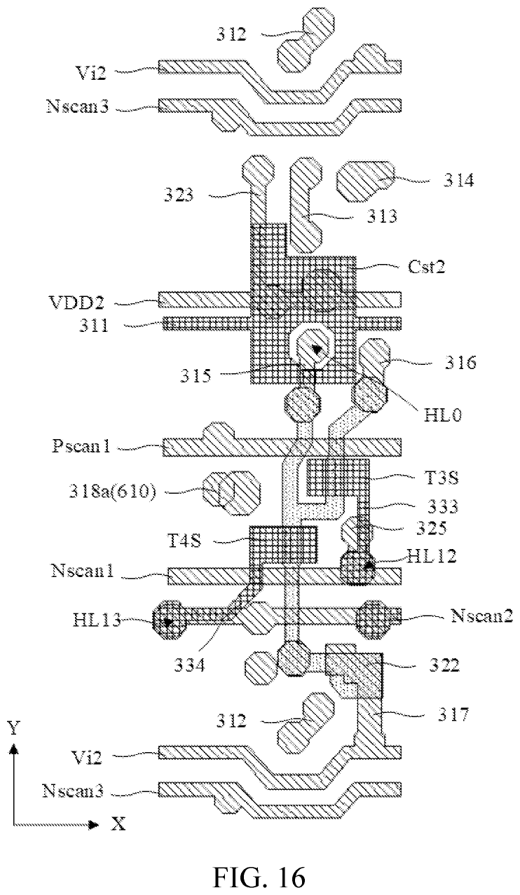

In the present embodiment, a first terminal of the fifth electrical connection section 315 is electrically connected to an end of the first extension section 321 away from the second control signal line Pscan1 through a sixth via hole HL6. A second terminal of the fifth electrical connection section 315 extends into the storage capacitor Cst, and is electrically connected to the first electrode plate Cst1 of the storage capacitor Cst through a seventh via hole HL7. In the structure of FIG. 16, the seventh via hole HL7 extends through the first via hole HL0 in the second electrode plate Cst2, a center of the first via hole HL0 and a center of the seventh via hole HL7 can be located on the same straight line perpendicular to a light exiting surface of the display panel 100. The fifth electrical connection section 315 of the present application serves as an electrical connection member, an end of the fifth electrical connection section 315 is electrically connected to the first extension section 321 through the sixth via hole HL6, and another end of the fifth electrical connection section 315 is electrically connected to the first electrode plate Cst1 of the storage capacitor Cst through the seventh via hole HL7. Namely, conductive lines of the third node Q in the first gate electrode layer 125 and the second active layer 129 are electrically connected to each other through metal of the first source and drain electrode layer 133.

In the present embodiment, a first terminal of the sixth electrical connection section 316 is electrically connected to the second connection point P2 of the first active layer 123 through an eighth via hole HL8. A second terminal of the sixth electrical connection section 316 is electrically connected to a second terminal of the compensation active portion T3A through a ninth via hole HL9.

In the present embodiment, the sixth via hole HL6 and the ninth via hole HL9 are defined through the fourth gate insulation layer 130 and the first interlayer insulation layer 132. The seventh via hole HL7 and the eighth via hole HL8 are defined through the first gate insulation layer 124, the second gate insulation layer 126, the third gate insulation layer 128, the fourth gate insulation layer 130, and the first interlayer insulation layer 132.

With reference to FIG. 14 to FIG. 17, the first source and drain electrode layer 133 further comprises a fifth extension section 325. An end of the fifth extension section 325 is electrically connected to the first control signal line Nscan1. The fifth extension section 325 extends away from a side of the first control signal line Nscan1 along the second direction Y. An end of the fifth extension section 325 away from the first control signal line Nscan1 is electrically connected to the first electrical conduction section 331 through a tenth via hole HL10. The first control signal line Nscan1 transmits a control signal to the compensation gate electrode T3G of the compensation transistor T3 by the fifth extension section 325 and the first electrical conduction section 331. Also, an end of the second electrical conduction section 332 away from the first reset gate electrode T4G overlaps the third control signal line Nscan2 and is electrically connected to the third control signal line Nscan2 through an eleventh via hole HL11. The third control signal line Nscan2 transmits a control signal to the first reset gate electrode T4G of the first reset transistor T4 by the second electrical conduction section 332.

In the present embodiment, the tenth via hole HL10 and the eleventh via hole HL11 are defined through the first interlayer insulation layer 132.

With reference to FIGS. 14 to 17, the third electrical conduction section 333 overlaps the first electrical conduction section 331 and the third electrical conduction section 333, and the third electrical conduction section 333 is electrically connected to the first control signal line Nscan1 through a twelfth via hole HL12. The first control signal line Nscan1 transmits a control signal to the first light shielding unit T3S by the third electrical conduction section 333. Namely, the first light shielding unit T3S can be reused as a bottom gate electrode of the compensation transistor T3. The compensation gate electrode T3G can be reused as a top gate electrode of the compensation transistor T3. The configuration of the first light shielding unit T3S and the compensation gate electrode T3G can increase a conductive rate of the compensation transistor T3, thereby increasing a device effect of the compensation transistor T3. The fourth electrical conduction section 334 overlaps a portion of the third control signal line Nscan2, and is electrically connected to the third control signal line Nscan2 through a thirteen via hole HL13. The third control signal line Nscan2 transmits a control signal to the second light shielding unit T4S by the fourth electrical conduction section 334. Namely, the second light shielding unit T4S can be reused as a bottom gate electrode of the first reset transistor T4. The first reset gate electrode T4G can be reused as a top gate electrode of the first reset transistor T4. The configuration of the second light shielding unit T4S and the first reset gate electrode T4G can increase a conductive rate of the first reset transistor T4, thereby increasing a device effect of the first reset transistor T4.

In the present embodiment, the twelfth via hole HL12 and the thirteen via hole HL13 are defined through the third gate insulation layer 128, the fourth gate insulation layer 130, and the first interlayer insulation layer 132.

It should be explained that the third electrical conduction section 333 can be disposed insulatively from the first control signal line Nscan1. The fourth electrical conduction section 334 can be disposed insulatively from the third control signal line Nscan2.

With reference to FIG. 14 to FIG. 17, the second control signal line Nscan3 can be connected to the fourth control signal line Pscan2 in parallel through a fourteen via hole HL14. Namely, a fifth control signal is connected to the fourth control signal line Pscan2 in parallel, thereby reducing resistances of the second control signal line Nscan3 and the fourth control signal line Pscan2.

In the present embodiment, the fourteen via hole HL14 is defined through the second gate insulation layer 126, the third gate insulation layer 128, the fourth gate insulation layer 130, and the first interlayer insulation layer 132.

With reference to FIGS. 14 to 17, the first control signal line Nscan1 partially overlaps the first reset active portion T4A, the second control signal line Pscan1 partially overlaps the first extension section 321, and the second control signal line Pscan1 partially overlaps the compensation active portion T3A, and the third control signal line Nscan2 partially overlaps the first reset active portion T4A. The four overlapping regions are overlaps of material of the second active layer 129 and material of the first source and drain electrode layer 133. The first source and drain electrode layer 133 and the second active layer 129 are spaced from each other by the fourth gate insulation layer 130 and the first interlayer insulation layer 132, no material of the third gate electrode layer 131 is disposed therebetween, thereby preventing a technical issue of the third gate electrode layer 131 easily shorting with the first source and drain electrode layer 133.

With reference to FIG. 14 to FIG. 17, a portion of the second control signal line Pscan1 overlapping the first extension section 321 is the boost capacitor Cboost of the present application. A third electrode plate of the boost capacitor Cboost can be a portion of the first extension section 321 overlapping the second control signal line Pscan1. A fourth electrode plate of the boost capacitor Cboost can be a portion of the second control signal line Pscan1 overlapping the first extension section 321

With reference to FIG. 14 to FIG. 17, the first source and drain electrode layer 133 further comprises a seventh electrical connection section 317 disposed between the second reset signal line Vi2 and the third control signal line Nscan2. The seventh electrical connection section 317 extends away from a side of the second reset signal line Vi2 along the second direction Y. The seventh electrical connection section 317 overlaps the second extension section 322. Namely, a capacitor is formed between the first reset signal line Vi1 and the second reset signal line Vi2, thereby guaranteeing stability of the voltage on the first reset signal line Vi1 and the second reset signal line Vi2.

In the present embodiment, the fifth electrical connection section 315 and the first extension section 321 are conductive lines in a region in which the third node of the present application is located. Namely, electric potentials of the fifth electrical connection section 315 and the first extension section 321 are an electric potential of the third node Q. Also, the second control signal line Pscan1 overlaps the first extension section 321 in a first region M1. Namely, the first extension section 321 of the present application is located in the second active layer 129, the second control signal line Pscan1 is located in the first source and drain electrode layer 133. Replacing some conductive lines in a region in which the third node Q is located from the third gate electrode layer 131 to the second active layer 129 of the present application avoids a technical issue of cracks of an upper layer insulation layer and prevents a technical issue of the horizontally disposed second control signal line Pscan1 from shorting with a conductive line of a lower layer in the first region M1.

Also, the first control signal line Nscan1 overlaps the compensation active portion T3A in a second region M2. The second control signal line Pscan1 overlaps the first reset active portion T4A in a third region M3. The third control signal line Nscan2 overlaps the first reset active portion T4A in a fourth region M4. Namely, the compensation active portion T3A and the first reset active portion T4A of the present application are located in the second active layer 129. The first control signal line Nscan1 and the third control signal line Nscan2 are located in the first source and drain electrode layer 133 such that the first control signal line Nscan1, the second control signal line Pscan1, and the third control signal line Nscan2 are replaced by changing a gate electrode layer with a greater resistance to the first source and drain electrode layer 133 with a smaller resistance, for example, they are replaced by changing original metal molybdenum to titanium aluminum titanium of the present application, thereby reducing the resistance of the three control signal lines. Second, because the overlap between the first source and drain electrode layer 133 and the third gate electrode layer 131 has a risk of shorting, the present application replaces the conductive line of the region in which the third node Q is located by changing the third gate electrode layer 131 to the second active layer 129, thereby avoiding the conductive line in the region in which the third node Q is located from shorting with the first source and drain electrode layer 133.

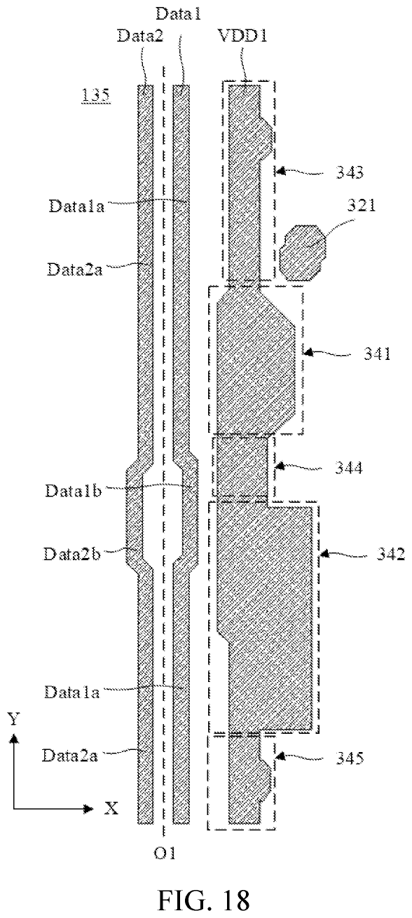

With reference to FIG. 18, the second source and drain electrode layer 135 comprises the first data signal line Data1, the second data signal line Data2, and the first high electrical potential line VDD1. The second data signal line Data2, the first data signal line Data1, and the first high electrical potential line VDD1 are arranged along the first direction X and extend along the second direction Y. The first data signal line Data1 is disposed between the second data signal line Data2 and the first high electrical potential line VDD1.

With reference to FIG. 18 to FIG. 20, the first high electrical potential line VDD1 comprises a first sub-plate 341, a second sub-plate 342, a third sub-plate 343, a fourth sub-plate 344, and a fifth sub-plate 345. The third sub-plate 343, the first sub-plate 341, the fourth sub-plate 344, the second sub-plate 342, and the fifth sub-plate 345 are disposed along the second direction Y. The first sub-plate 341 is disposed between the third sub-plate 343 and the fourth sub-plate 344. The second sub-plate 342 is disposed between the fourth sub-plate 344 and the fifth sub-plate 34. In the first direction X, a width of the first sub-plate 341 is less than a width of the second sub-plate 342. The width of the first sub-plate 341 can be greater than a width of the fourth sub-plate 344. The width of the fourth sub-plate 344 can be greater than or equal to widths of the third sub-plate 343 and the fifth sub-plate 345.

In the present embodiment, because an electric potential of the driver gate electrode T1G is an electric potential of the third node Q, variation of the electric potential of the third node Q directly affects a work current of the light emitting device 211b. Thus, the present application needs to guarantee the stability of the electric potential of the third node Q. The present application can locate an orthographic projection of the driver gate electrode T1G on the first high electrical potential line VDD1 in the first sub-plate 341. Namely, the first sub-plate 341 is used as a shielding layer to maintain the stability of the third node Q electric potential. Therefore, the present application needs to increase a horizontal width of the first sub-plate 341 such that the first sub-plate 341 completely covers the driver gate electrode T1G. The first electrode plate Cst1 of the storage capacitor Cst is reused as the driver gate electrode T1G. Namely, an orthographic projection of the first electrode plate Cst1 on the first high electrical potential line VDD1 can be located in the first sub-plate 341. Thus, a width of the first sub-plate 341 of the present application can be greater than widths of the third sub-plate 343, the fourth sub-plate 344, and the fifth sub-plate 345.

In the present embodiment, the fifth electrical connection section 315 and the first extension section 321 are electrically connected to the driver gate electrode T1G. Therefore, variation of electric potentials of the fifth electrical connection section 315 and the first extension section 321 also affects an electric potential of the driver gate electrode T1G. Thus, the present application can increase a width of the fourth sub-plate 344 to completely cover the fifth electrical connection section 315 and the first extension section 321. As such, a horizontal width of the fourth sub-plate 344 of the present application can be greater than horizontal widths of the third sub-plate 343 and the fifth sub-plate 345.

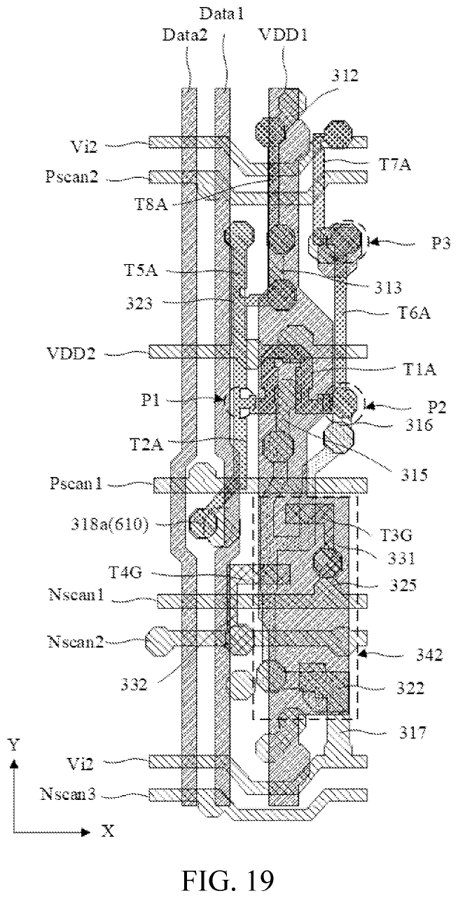

With reference to FIG. 18 and FIG. 19, an orthographic projection of the compensation gate electrode T3G on the first high electrical potential line VDD1 is located in the second sub-plate 342. A portion of the first high electrical potential line VDD1 overlaps the compensation gate electrode T3G and a portion of the first control signal line Nscan1, and the two can form a capacitor, thereby increasing an anti-coupling ability of the first control signal line Nscan1 to further increase the stability of the control signal transmitted by the first control signal line Nscan1 to avoid switch abnormality of the compensation transistor T3 and guarantee the stability of the electric potential of the gate electrode of the driver transistor T1.

With reference to FIG. 18 to FIG. 20, the first source and drain electrode layer 133 of the first sub-pixel unit 211c can comprise an eighth electrical connection section 318a disposed between the first control signal line Nscan1 and the second control signal line Pscan1. An end of the eighth electrical connection section 318a is electrically connected to a second terminal of the switch active portion T2A, and another end of the eighth electrical connection section 318a is electrically connected to the first data signal line Data1. The first data signal line Data1 transmits a data signal to the switch transistor T2 by the eighth electrical connection section 318a.

In the present embodiment, the eighth electrical connection section 318a in FIG. 18 to FIG. 20 can be the first electrical connection member 610 of the first sub-pixel unit 211c of the present application. Namely, the switch active portion T2A of the first sub-pixel unit 211c is electrically connected to the first data signal line Data1 by the first electrical connection member 610.

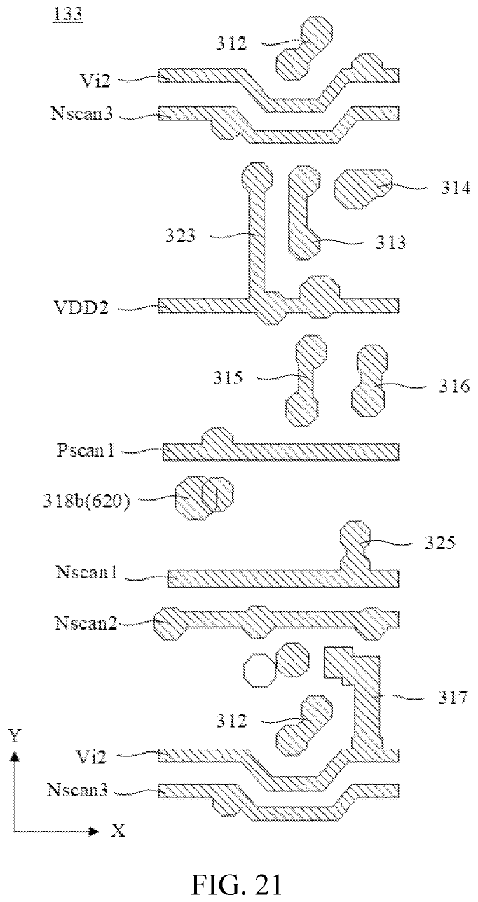

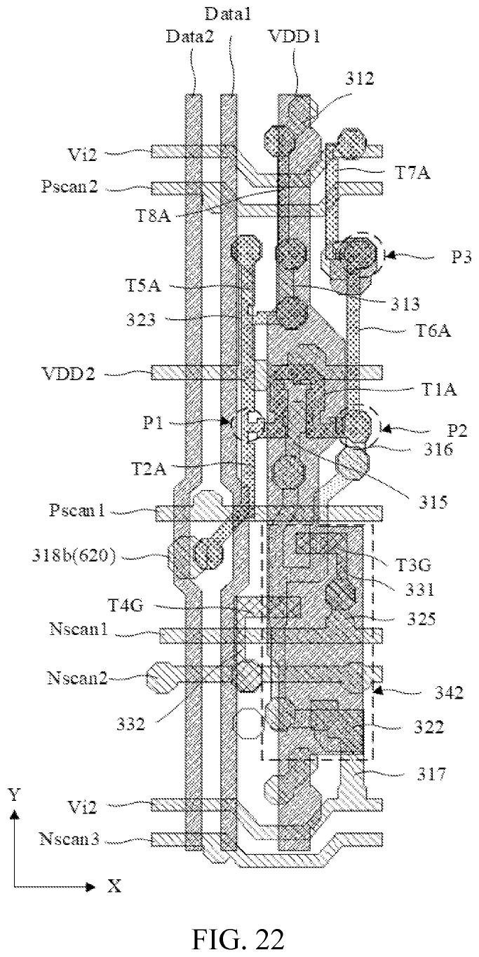

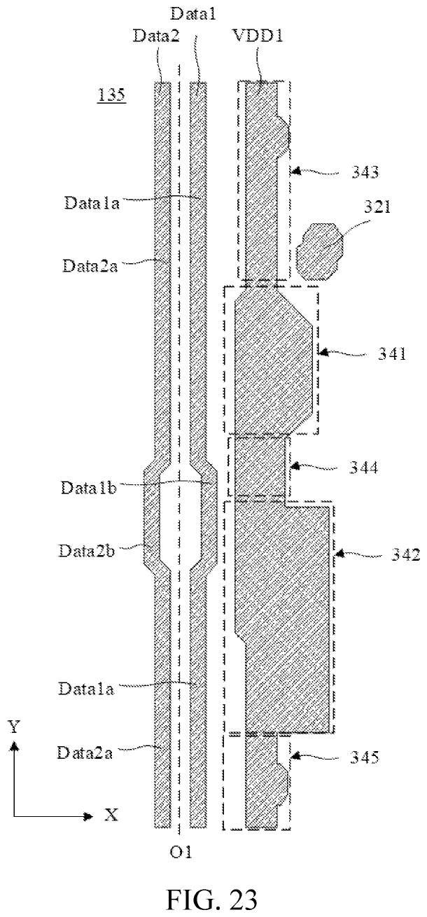

With reference to FIGS. 21 and 22, the first source and drain electrode layer 133 of the second sub-pixel unit 211d can comprise an eighth electrical connection section 318b disposed between the first control signal line Nscan1 and the second control signal line Pscan1. An end of the eighth electrical connection section 318b is electrically connected to a second terminal of the switch active portion T2A, and another end of the eighth electrical connection section 318b is electrically connected to the second data signal line Data2. The second data signal line Data2 transmits a data signal to the switch transistor T2 by the eighth electrical connection section 318b.

In the present embodiment, the eighth electrical connection section 318b in FIG. 21 and FIG. 22 can be the second electrical connection member 620 of the second sub-pixel unit 211d of the present application. Namely, the switch active portion T2A of the second sub-pixel unit 211d is electrically connected to the second data signal line Data2 by the second electrical connection member 620.

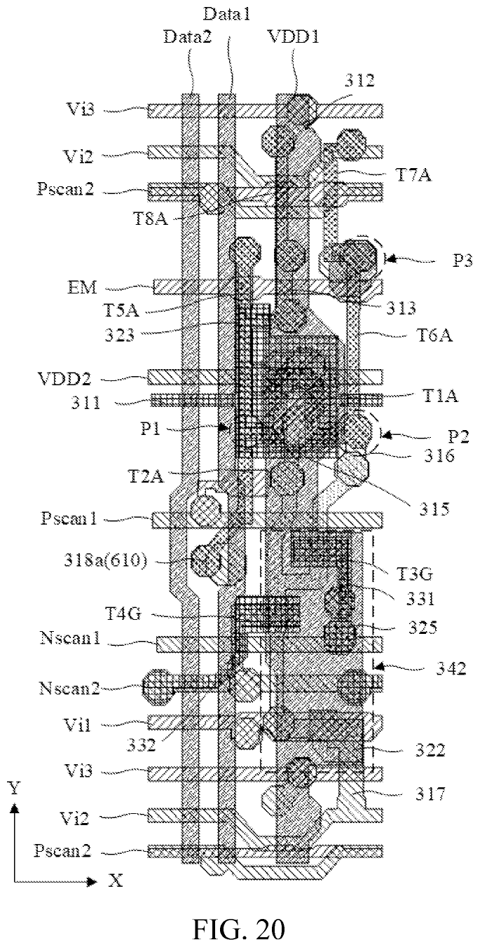

In the structure of FIG. 2, the present application sets forth six sub-pixel units 211, the sub-pixel units 211 in the first row are connected to the first data signal line Data1, and the sub-pixel units 211 in the second row are connected to the second data signal line Data2. The sub-pixel units 211 set forth by the present application in FIG. 19 and FIG. 20 are the first sub-pixel units 211c of the first row in FIG. 2. The sub-pixel units 211 set forth by the present application in FIG. 21 and FIG. 22 are the second sub-pixel units 211d of the second row in FIG. 2.

In FIG. 19 and FIG. 22, the switch active portion T2A of the first sub-pixel unit 211c and the switch active portion T2A of the second sub-pixel unit 211d extend toward a location between the first data signal line Data1 and the second data signal line Data2, and partially overlap one of the first data signal line Data1 and the second data signal line Data2. The switch active portion T2A of the first sub-pixel unit 211c and the switch active portion T2A of the second sub-pixel unit 211d in FIG. 19 and FIG. 22 overlap the first data signal line Data1.

In FIG. 19 and FIG. 22, because patterns of the switch active portion T2A of the first sub-pixel unit 211c and the switch active portion T2A of the second sub-pixel unit 211d are the same, the switch active portion T2A of the first sub-pixel unit 211c comprises a first connection terminal electrically connected to the first electrical connection member 610, the switch active portion T2A of the second sub-pixel unit 211d comprises a second connection terminal electrically connected to the second electrical connection member 620, and a central connection line between the first connection terminal and the second connection terminal is parallel to the second direction Y. Also, the first connection terminal and the second connection terminal are disposed between the first data signal line Data1 and the second data signal line Data2.

In FIG. 19 and FIG. 22, the first electrical connection member 610 extends near a side the repeat units 500, the second electrical connection member 620 extends away from a side of the repeat units 500, and the first electrical connection member 610 partially overlaps the first data signal line Data1 such that the first electrical connection member 610 is electrically connected to the first data signal line Data1. The first electrical connection member 610 does not overlap the second data signal line Data2, the second electrical connection member 620 partially overlaps the second data signal line Data2, the second electrical connection member 620 does not overlap the first data signal line Data1 such that the second electrical connection member 620 is electrically connected to the second data signal line Data2.

With reference to FIG. 19, the first data signal line Data1 comprises a plurality of first vertical sections Data1a and a first avoidance section Data1b disposed between adjacent two of the first vertical sections Data1a. An interval between the first avoidance section Data1b and the repeat units 500 is less than an interval between the first vertical sections Data1a and the repeat units 500. The switch active portion T2A of the first sub-pixel unit 211c is electrically connected to the first avoidance section Data1b by the first electrical connection member 610.

With reference to FIG. 22, the second data signal line Data2 comprises a plurality of second vertical sections Data2a and a second avoidance section Data2b disposed between adjacent two of the second vertical sections Data2a. The first avoidance section Data1b is disposed opposite to and parallel to the second avoidance section Data2b. An interval between the second avoidance section Data2b and the repeat units 500 is greater than an interval between the second vertical sections Data2a and the repeat units 500. The switch active portion T2A of the second sub-pixel unit 211d is electrically connected to the second avoidance section Data2b by the second electrical connection member 620.

Configuration of the first avoidance section Data1b and the second avoidance section Data2b of the present application mainly lies in that the first avoidance section Data1b needs to pass through a via hole to be electrically connected to the first electrical connection member 610, and the second avoidance section Data2b needs to pass through a corresponding via hole to be electrically connected to the second electrical connection member 620. To avoid interference of the via holes with adjacent data signal lines, avoidance sections are disposed at the locations of via holes.

With reference to FIG. 18, a middle axial line O1 is defined between the first data signal line Data1 and the second data signal line Data2. The first avoidance section Data1b and the second avoidance section Data2b are symmetrically disposed according to the middle axial line O1.

With reference to FIG. 23, the middle axial line O1 is defined between the first data signal line Data1 and the second data signal line Data2. An interval between the first avoidance section Data1b and the middle axial line O1 is less than an interval between the second avoidance section Data2b and the middle axial line O1. Because the interval between the first avoidance section Data1b and the adjacent first high electrical potential line VDD1 is less than the interval between the second avoidance section Data2b and the adjacent first high electrical potential line VDD1, the present application can reduce the interval between the first avoidance section Data1b and the middle axial line O1 such that the interval between the first avoidance section Data1b and the adjacent first high electrical potential line VDD1 and the interval between the second avoidance section Data2b and the adjacent first high electrical potential line VDD1 are equal, thereby avoiding a capacitor difference between the data signal line and the first high electrical potential line VDD1 resulting in difference between data signals transmitted by the first data signal line Data1 and the second data signal line Data2.

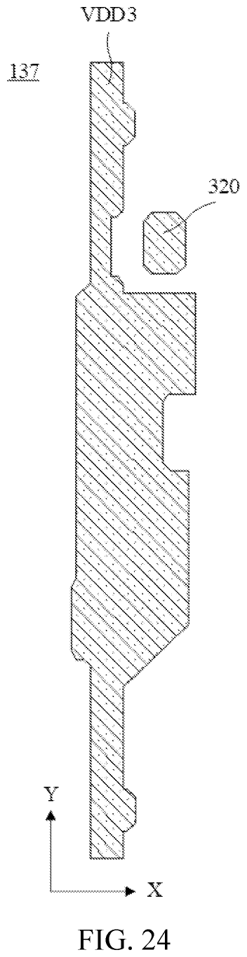

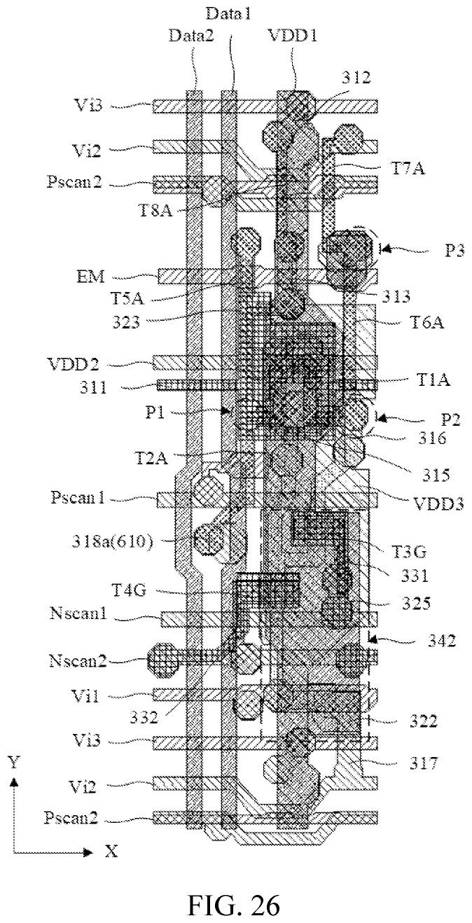

With reference to FIGS. 24 and 26, the third source and drain electrode layer 137 can comprise a third high electrical potential line VDD3 extending along the second direction Y. The third high electrical potential line VDD3 is electrically connected to the second high electrical potential line VDD2. The configuration of the third high electrical potential line VDD3 is mainly configured to reduce a resistance of the conductive line transmitting a constant voltage high level.

It should be explained that in FIG. 18 to FIG. 24, the first high electrical potential line VDD1 of the present application can be electrically connected to the second high electrical potential line VDD2. Second, the second high electrical potential line VDD2 is electrically connected to the second electrode plate Cst2 of the storage capacitor Cst. The second electrode plate Cst2 in the same row is electrically connected by the first electrical connection section 311. Therefore, the conductive line of the present application configured to transmit a constant voltage high level has four layers of metal which are the second electrode plate Cst2 and the first electrical connection section 311 located in the second gate electrode layer 127, the second high electrical potential line VDD2 located in the first source and drain electrode layer 133, the first high electrical potential line VDD1 located in the second source and drain electrode layer 135, and the third high electrical potential line VDD3 located in the third source and drain electrode layer 137. The second electrode plate Cst2, the first electrical connection section 311, the second high electrical potential line VDD2 extend along the first direction X. The first high electrical potential line VDD1 and the third high electrical potential line VDD3 extend along the second direction Y. Therefore, the present application uses the four layers of metal to transmit the constant voltage high level to form a crisscrossing metal mesh to reduce the resistance of the conductive line to further reduce a loss of the constant voltage high level during transmission on the conductive line.

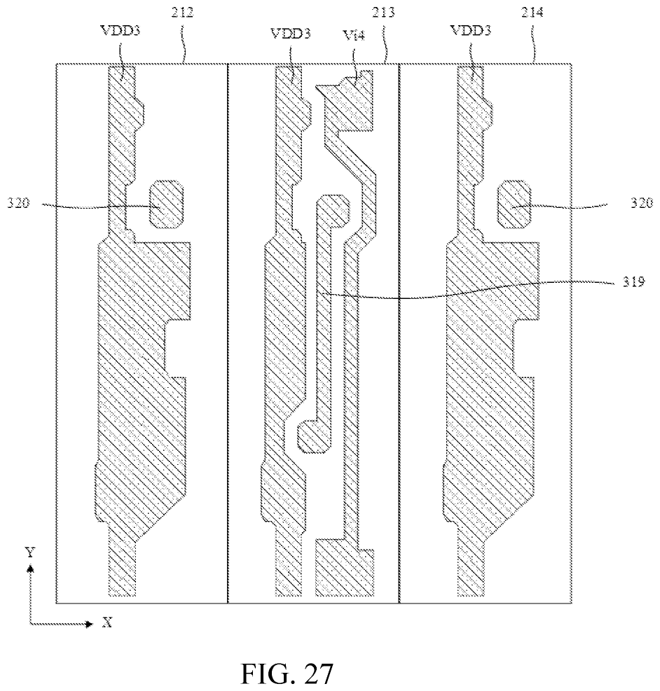

With reference to FIG. 27, the third source and drain electrode layer 137 of the present application comprises a plurality of electrical potential line units 137a. Each of the electrical potential line units 137a is arranged along the first direction X and corresponds to adjacent three of the sub-pixel units 211, for example, a red sub-pixel unit 212, a green sub-pixel unit 213, and a blue sub-pixel unit 214. For example, the three sub-pixel units 211 are the red sub-pixel unit 212, the green sub-pixel unit 213, and the blue sub-pixel unit 214. Each of the electrical potential line units 137a can comprise a first one of the third high electrical potential lines VDD3 corresponding to the red sub-pixel unit 212, a third one of the third high electrical potential lines VDD3 corresponding to the blue sub-pixel unit 214, a second one of the high electrical potential lines corresponding to the green sub-pixel unit 213, and a fourth reset signal line Vi4. Patterns of the first one of the third high electrical potential lines VDD3 and the third one of the third high electrical potential lines VDD3 can be the same. A pattern of the second one of the third high electrical potential lines VDD3 can be different from that of the third one of the third high electrical potential lines VDD. Also, a horizontal width of the second one of the third high electrical potential lines VDD3 is less than a horizontal width of the third one of the third high electrical potential lines VDD3.

It should be explained that the above sub-pixel colors corresponding to three high electrical potential lines can be arranged randomly without limit by the above embodiment.

With reference to FIG. 27, one vertical reset signal line and three horizontal reset signal lines are disposed in each of the electrical potential line units 137a. Namely, each of the electrical potential line units 137a can further comprise the fourth reset signal line Vi4 located in the green sub-pixel unit 213. The fourth reset signal line Vi4 in each of the electrical potential line units 137a is electrically connected to one of the first reset signal line Vi1, the second reset signal line Vi2, and the third reset signal line Vi3, and the fourth reset signal lines Vi4 of adjacent three of the electrical potential line units 137a are connected to different reset signal lines.

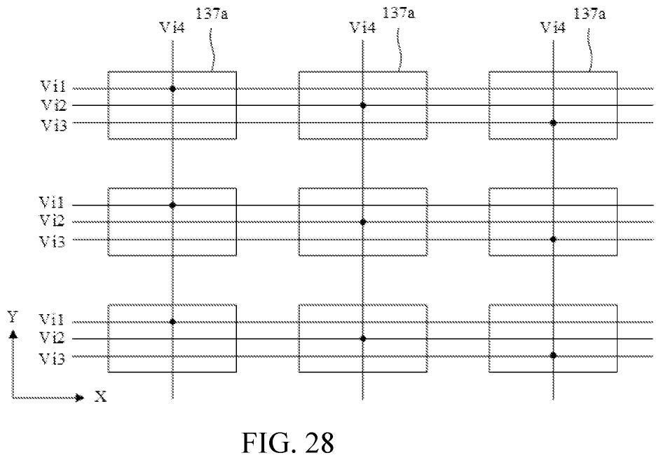

In the present application, to reduce a resistance of a reset signal line, the vertically disposed reset signal line can be electrically connected to one of three horizontal reset signal lines. For example, in FIG. 28, three rows of the electrical potential line units 137a are disposed, and each row of the electrical potential line units 137a comprises the three electrical potential line units 137a. One fourth reset signal line Vi4 is disposed in each of the electrical potential line units 137a. The fourth reset signal line Vi4 in a first one of the electrical potential line units 137a can be electrically connected to the first reset signal line Vi1 of each row. The fourth reset signal line Vi4 of a second one of the electrical potential line units 137a can be electrically connected to the second reset signal line Vi2 of each row. The fourth reset signal line Vi4 of a third one of the electrical potential line units 137a can be electrically connected to the third reset signal line Vi3 of each row such that each horizontally disposed reset signal line is electrically connected to the fourth reset signal line Vi4 to form a crisscrossing metal mesh, thereby reducing a resistance of the reset signal line.

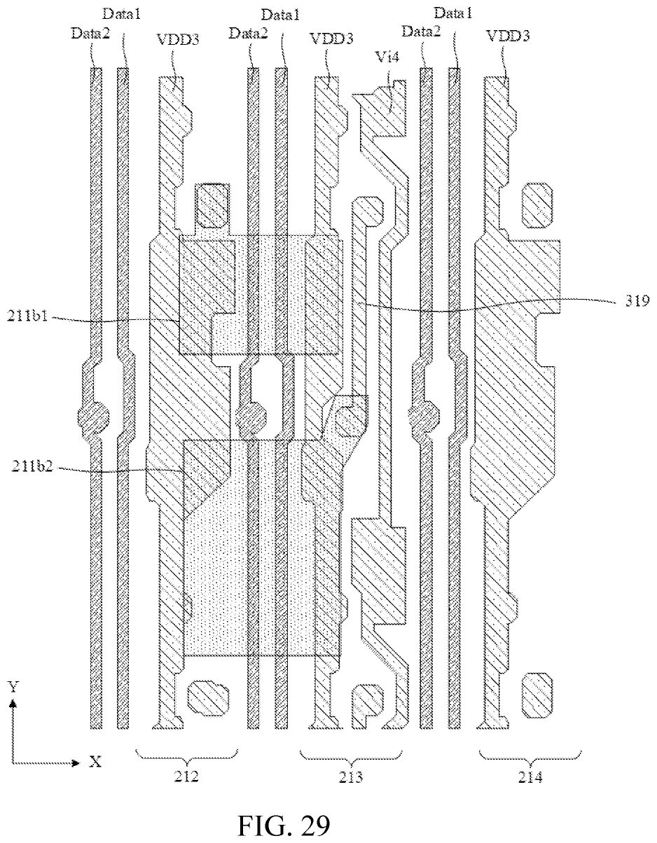

It should be explained that in FIG. 27, a first sub-pixel unit 212, a second sub-pixel unit 213, and a third sub-pixel unit 214 only represent locations of the pixel driver circuits 211a corresponding to the sub-pixel units 211, and locations of the anodes of the sub-pixel units 211 can be not in the corresponding regions. For example, with reference to FIG. 29, the pixel driver circuit 211a of the first sub-pixel unit 212 of the present application is electrically connected to a first anode 211b1, and the pixel driver circuit 211a of the second sub-pixel unit 213 is electrically connected to a second anode 211b2. The first anode 211b1 and the second anode 211b2 are arranged along the second direction Y. The first anode 211b1 and the second anode 211b2 cross the first sub-pixel unit 212 and the second sub-pixel unit 213.

It should be explained that in FIG. 29, the third source and drain electrode layer 137 can further comprise a ninth electrical connection section 319 and a tenth electrical connection section 320. The ninth electrical connection section 319 is disposed between the fourth reset signal line Vi4 and a second one of the third high electrical potential lines VDD3. The tenth electrical connection section 320 is disposed on a side of the first one of the third high electrical potential lines VDD3 and the third one of the third high electrical potential lines VDD3. The tenth electrical connection section 320 corresponds to the fourth electrical connection section 314. The second source and drain electrode layer 135 can further comprise an eleventh electrical connection section 321. The second anode 211b2 can be electrically connected to the third connection point P3 of the first active layer 123 of the pixel driver circuit 211a of the second sub-pixel unit 213 by the ninth electrical connection section 319, the eleventh electrical connection section 321, and the fourth electrical connection section 314 of the second sub-pixel unit 213. Similarly, the first anode 211b1 can be electrically connected to the third connection point P3 of the first active layer 123 of the pixel driver circuit 211a of the first sub-pixel unit 212 by the tenth electrical connection section 320, the eleventh electrical connection section 321, and the fourth electrical connection section 314 of the first sub-pixel unit 212. Similarly, a connection way of an anode of a third sub-pixel unit 314 is the same as a connection way of the first anode 211b1.

The present application also provides a display device, and the display device comprises the above display panel. The display device can be: cell phone, tablet, television, monitor, laptop computer, digital photo frame, navigator and any other product or component with the display function.

In the above-mentioned embodiments, the descriptions of the various embodiments are focused. For the details of the embodiments not described, reference may be made to the related descriptions of the other embodiments.

The display panel and the display device provided by the embodiment of the present application are described in detail as above. The principles and implementations of the present application are described in the following by using specific examples. The description of the above embodiments is only for assisting understanding of the technical solutions of the present application and the core ideas thereof. Those of ordinary skill in the art should understand that they can still modify the technical solutions described in the foregoing embodiments or equivalently replace some of the technical features. These modifications or replacements do not make the essence of the technical solutions depart from a range of the technical solutions of the embodiments of the present application.

1. A display panel, comprising a plurality of repeat units, and a first data signal line and a second data signal line disposed on a side of the repeat units, the repeat units comprising at least one first sub-pixel unit and at least one second sub-pixel unit, and each of the first sub-pixel unit and the second sub-pixel unit comprising a pixel driver circuit and a light emitting device connected to the pixel driver circuit;
wherein the display panel further comprises a first electrical connection member and a second electrical connection member, the pixel driver circuit of the first sub-pixel unit is electrically connected to the first data signal line by the first electrical connection member, the pixel driver circuit of the second sub-pixel unit is electrically connected to the second data signal line by the second electrical connection member, and the first electrical connection member, the second electrical connection member, the first data signal line, and the second data signal line are disposed on a same side of the repeat units.

2. The display panel according to claim 1, wherein the pixel driver circuit of each of the first sub-pixel unit and the second sub-pixel unit comprises a switch transistor, a driver transistor, and a compensation transistor connected together, and the switch transistor comprises a switch active portion; and
wherein the switch active portion of the first sub-pixel unit is electrically connected to the first data signal line by the first electrical connection member, and the switch active portion of the second sub-pixel unit is electrically connected to the second data signal line by the second electrical connection member.

3. The display panel according to claim 2, wherein a pattern of the switch active portion of the first sub-pixel unit is the same as a pattern of the switch active portion of the second sub-pixel unit;
wherein the switch active portion of the first sub-pixel unit and the switch active portion of the second the sub-pixel unit Partially overlap one of the first data signal line and the second data signal line.

4. The display panel according to claim 3, wherein the switch active portion of the first sub-pixel unit comprises a first connection terminal electrically connected to the first electrical connection member, and the switch active portion of the second sub-pixel unit comprises a second connection terminal electrically connected to the second electrical connection member;
wherein the first connection terminal and the second connection terminal are disposed between the first data signal line and the second data signal line, and a central connection line between the first connection terminal and the second connection terminal is parallel to a second direction.

5. The display panel according to claim 3, wherein the first data signal line is disposed between the repeat units and the second data signal line;
wherein the first electrical connection member extends near a side of the repeat units, the second electrical connection member extends away from a side of the repeat units, the first electrical connection member partially overlaps the first data signal line, the first electrical connection member does not overlap the second data signal line, the second electrical connection member partially overlaps the second data signal line, and the second electrical connection member does not overlap the first data signal line.

6. The display panel according to claim 5, wherein the first data signal line comprises a plurality of first vertical sections and a first avoidance section disposed between adjacent two of the first vertical sections, the second data signal line comprises a plurality of second vertical sections and a second avoidance section disposed between adjacent two of the second vertical sections, and the first avoidance section is opposite and parallel to the second avoidance section;
wherein an interval between the first avoidance section and the repeat units is less than an interval of the first vertical sections between the repeat units, an interval between the second avoidance section and the repeat units is greater than an interval between the second vertical sections and the repeat units, the switch active portion of the first sub-pixel unit is electrically connected to the first avoidance section by the first electrical connection member, and the switch active portion of the second sub-pixel unit is electrically connected to the second avoidance section by the second electrical connection member.

7. The display panel according to claim 6, wherein a middle axial line is disposed between the first data signal line and the second data signal line, and the first avoidance section and the second avoidance section are disposed symmetrically relative to the middle axial line.

8. The display panel according to claim 2, wherein a first electrode of the switch transistor is connected to one of the first data signal line or the second data signal line, and a second electrode of the switch transistor is connected to a first node;
a first electrode of the driver transistor is connected to the first node, a second electrode of the driver transistor is connected to a second node, and a driver gate electrode of the driver transistor is connected to a third node;
a first electrode of the compensation transistor is connected to the third node, and a second electrode of the compensation transistor is connected to the second node;
wherein a compensation gate electrode of the compensation transistor is connected to a first control signal line, a switch gate electrode of the switch transistor is connected to second control signal line, and the first electrical connection member and the second electrical connection member are disposed between the first control signal line and the second control signal line of a corresponding one of the pixel driver circuits.

9. The display panel according to claim 1, wherein the pixel driver circuit further comprises:
a first reset transistor, wherein a first electrode of the first reset transistor is connected to a first reset signal line, a second electrode of the first reset transistor is connected to a third node, and a first reset gate electrode of the first reset transistor is connected to a third control signal line;
a second reset transistor, wherein a first electrode of the second reset transistor is connected to a second reset signal line, a second electrode of the second reset transistor is connected to an anode of the light emitting device, and a second reset gate electrode of the second reset transistor is connected to a fourth control signal line;
a third reset transistor, wherein a first electrode of the third reset transistor is connected to a third reset signal line, a second electrode of the third reset transistor is connected to a first node, and a third reset gate electrode of the third reset transistor is connected to the fourth control signal line;
a first light emitting transistor, wherein a first electrode of the first light emitting transistor is connected to a first high electrical potential line, a second electrode of the first light emitting transistor is connected to the first node, and a first light emitting gate electrode of the first light emitting transistor is connected to a light emitting signal line;
a second light emitting transistor, wherein a first electrode of the second light emitting transistor is connected to a second node, a second electrode of the second light emitting transistor is connected to an anode of the light emitting device, and a second light emitting gate electrode of the second light emitting transistor is connected to the light emitting signal line;
a storage capacitor, wherein the storage capacitor comprises a first electrode plate and a second electrode plate, the first electrode plate is connected to the third node, and the second electrode plate is connected to the first high electrical potential line;
a boost capacitor, wherein the boost capacitor comprises a third electrode plate and a fourth electrode plate, the third electrode plate is connected to the third node, and the fourth electrode plate is connected to a second control signal line.

10. The display panel according to claim 9, wherein a capacitor value of the boost capacitor is less than a capacitor value of the storage capacitor.

11. The display panel according to claim 9, wherein a first gate electrode layer of the display panel comprises a light emitting signal line, a first reset signal line, a third reset signal line, a fourth control signal line, each of the light emitting signal line, the first reset signal line, the third reset signal line, and the fourth control signal line extends along a first direction, and the third reset signal line, the fourth control signal line, the light emitting signal line, and the first reset signal line are arranged at intervals along a second direction.

12. The display panel according to claim 11, wherein a first active layer of the display panel comprises a switch active portion of the switch transistor, a driver active portion of the driver transistor, a second reset active portion of the second reset transistor, a third reset active portion of the third reset transistor, a first light emitting active portion of the first light emitting transistor, and a second light emitting active portion of the second light emitting transistor;
wherein the switch active portion, the driver active portion, the second reset active portion, the first light emitting active portion, and the second light emitting active portion are connected together, the switch active portion, the second reset active portion, the third reset active portion, the first light emitting active portion, and the second light emitting active portion extend along the second direction, and the driver active portion are disposed between the first light emitting active portion and the second light emitting active portion.

13. The display panel according to claim 12, wherein a second gate electrode layer of the display panel comprises a second electrode plate of the storage capacitor disposed along the second direction, a first light shielding unit of the compensation transistor, a second light shielding unit of the first reset transistor, the second electrode plate, the first light shielding unit, and the second light shielding unit are located between the light emitting signal line the first reset signal line, the first electrode plate is disposed near the light emitting signal line, the second light shielding unit is disposed near the first reset signal line, and the first light shielding unit is located between the second light shielding unit and the second electrode plate.

14. The display panel according to claim 13, wherein the second gate electrode layer further comprises two first electrical connection sections disposed respectively on two sides of the second electrode plate, the first electrical connection sections extend along the first direction, and in adjacent two of the sub-pixel units disposed along the first direction, the second electrode plates of the sub-pixel units are electrically connected to each other by the first electrical connection section.

15. The display panel according to claim 13, wherein a second active layer of the display panel comprises a compensation active portion of the compensation transistor and a first reset active portion of the first reset transistor, the compensation active portion and the first reset active portion extend along the second direction, a first terminal of the compensation active portion is electrically connected to a first terminal of the first reset active portion, and a second terminal of the first reset active portion extends toward the first reset signal line and overlaps the first reset signal line.

16. The display panel according to claim 15, wherein the second active layer further comprises a first extension section and a second extension section connected to a second terminal of the first reset active portion, the first extension section extends along the second direction and extends toward a location at which the storage capacitor is located, the first extension section is separated from the storage capacitor, the second extension section extends along the first direction, and the second extension section at least partially overlaps the first reset signal line.

17. The display panel according to claim 15, wherein a third gate electrode layer of the display panel comprises a compensation gate electrode of the compensation transistor and a first reset gate electrode of the first reset transistor, an area of the compensation gate electrode is less than an area of the first light shielding unit, an orthographic projection of the compensation gate electrode on the first light shielding unit is located in the first light shielding unit, an area of the first reset gate electrode is less than an area of the second light shielding unit, and an orthographic projection of the first reset gate electrode on the second light shielding unit is located in the second light shielding unit.

18. The display panel according to claim 17, wherein the third gate electrode layer further comprises a first electrical conduction section connected to the compensation gate electrode and a second electrical conduction section connected to the first reset gate electrode, the first electrical conduction section extends along the second direction and toward a side of away from the compensation gate electrode, and the second electrical conduction section extends along the second direction and toward a side away from the first reset gate electrode.

19. The display panel according to claim 18, wherein a first source and drain electrode layer of the display panel comprises a second reset signal line, a the fifth control signal line, a second high electrical potential line, a second control signal line, a first control signal line, and a third control signal line arranged along the second direction, and each of the second reset signal line, the fifth control signal line, the second high electrical potential line, the second control signal line, the first control signal line, and the third control signal line extends along the first direction.

20. A display device, comprising a display panel, and the display panel comprising a plurality of repeat units, and a first data signal line and a second data signal line disposed on a side of the repeat units, the repeat units comprising at least one first sub-pixel unit and at least one second sub-pixel unit, and each of the first sub-pixel unit and the second sub-pixel unit comprising a pixel driver circuit and a light emitting device connected to the pixel driver circuit;
wherein the display panel further comprises a first electrical connection member and a second electrical connection member, the pixel driver circuit of the first sub-pixel unit is electrically connected to the first data signal line by the first electrical connection member, the pixel driver circuit of the second sub-pixel unit is electrically connected to the second data signal line by the second electrical connection member, and the first electrical connection member, the second electrical connection member, the first data signal line, and the second data signal line are disposed on a same side of the repeat units.
